(19) United States
(12) Patent Application Publication
(10) Pub. No.: US 2025/0317239 A1
(43) Pub. Date: Oct. 9, 2025

(54) METHODS AND APPARATUS FOR ERROR CORRECTION CODING INTEGRATED WITH TRANSMISSION DIVERSITY

(71) Applicant: Polaran Haberlesme Teknolojileri Anonim Sirketi, Cankaya (TR)

(72) Inventor: Erdal ARIKAN, Ankara (TR)

(21) Appl. No.: 19/169,862

(22) Filed: Apr. 3, 2025

Related U.S. Application Data
(60) Provisional application No. 63/574,138, filed on Apr. 3, 2024.
(60) Provisional application No. 63/638,832, filed on Apr. 25, 2024.

(51) Int. Cl. H04L 1/02; H04L 1/00; H04L 5/00

(52) U.S. Cl. CPC H04L 1/02; H04L 1/0057; H04L 5/0091

(57) ABSTRACT

The disclosure relates to a 5G or 6G communication system for supporting a higher data transmission rate. The present disclosure discloses a method and an apparatus for error correction coding in a communication system, more specifically, to error correction coding integrated with transmission diversity.

### CROSS-REFERENCE TO RELATED APPLICATIONS

This application is based on and claims the benefit of U.S. Provisional Patent Application No. 63/574,138, filed on Apr. 3, 2024, and U.S. Provisional Patent Application No. 63/638,832 filed on Apr. 25, 2024, the disclosures of which are incorporated by reference herein in their entirety.

### BACKGROUND

### 1. Field

The present disclosure is directed generally to error correction coding in a communication system, more specifically, to error correction coding integrated with transmission diversity.

### 2. Description of Related Art

5^{th} generation (5G) mobile communication technologies define broad frequency bands to provide higher transmission rates and new services, and can be implemented in “Sub 6 GHz” bands such as 3.5 GHz, and also in “above 6 GHz” bands, which may be referred to as mmWave bands including 28 GHz and 39 GHz. In addition, the implementation of 6^{th} generation 6G mobile communication technologies (e.g., beyond 5G systems) in terahertz bands (e.g., 95 GHz to 3 THz bands) has been proposed in order to achieve transmission rates fifty times faster than 5G mobile communication technologies and ultra-low latencies one-tenth of 5G mobile communication technologies.

Since the beginning of the development of 5G mobile communication technologies, in order to support various services and to satisfy performance requirements in connection with enhanced mobile broadband (eMBB), ultra reliable low latency communications (URLLC), and massive machine-type communications (mMTC), there has been ongoing standardization regarding beamforming and massive multi-input multi-output (MIMO) for mitigating radio-wave path loss and increasing radio-wave transmission distances in mmWave, supporting numerologies (e.g., operating multiple subcarrier spacings (SCSs)) for efficiently utilizing mmWave resources and dynamic operation of slot formats, initial access technologies for supporting multi-beam transmission and broadbands, definition and operation of a bandwidth part (BWP), new channel coding methods such as a low density parity check (LDPC) code for large amount of data transmission and a polar code for highly reliable transmission of control information, layer 2 (L2) pre-processing, and network slicing for providing a dedicated network specialized to a specific service.

Currently, there are ongoing discussions regarding improvement and performance enhancement of initial 5G mobile communication technologies in view of services to be supported by 5G mobile communication technologies, and there has been physical layer standardization regarding technologies such as vehicle-to-everything (V2X) for aiding driving determination by autonomous vehicles based on information regarding positions and states of vehicles transmitted by the vehicles and for enhancing user convenience, new radio (NR)-Unlicensed (U) aimed at system operations conforming to various regulation-related requirements in unlicensed bands, NR UE (User Equipment) power saving, non-terrestrial network (NTN), which is UE-satellite direct communication for providing coverage in an area in which communication with terrestrial networks is unavailable, and positioning.

There has also been ongoing standardization in air interface architecture/protocol regarding technologies such as industrial Internet of things (IIoT) for supporting new services through interworking and convergence with other industries, integrated access and backhaul (IAB) for providing a node for network service area expansion by supporting a wireless backhaul link and an access link in an integrated manner, mobility enhancement including conditional handover and dual active protocol stack (DAPS) handover, and two-step random access for simplifying random access procedures (2-step RACH for NR).

There also has been ongoing standardization in system architecture/service regarding a 5G baseline architecture (e.g., service based architecture or service based interface) for combining network functions virtualization (NFV) and software-defined networking (SDN) technologies, and mobile edge computing (MEC) for receiving services based on UE positions.

As 5G mobile communication systems are commercialized, an exponentially increasing number of connected devices will be connected to communication networks, and it is expected that enhanced functions and performances of 5G mobile communication systems and integrated operations of connected devices will be necessary. To this end, new research is scheduled in connection with extended reality (XR) for efficiently supporting augmented reality (AR), virtual reality (VR), mixed reality (MR), etc., 5G performance improvement and complexity reduction by utilizing artificial intelligence (AI) and machine learning (ML), AI service support, metaverse service support, and drone communication.

Such development of 5G mobile communication systems will serve as a basis for developing new waveforms for providing coverage in terahertz bands of 6G mobile communication technologies, multi-antenna transmission technologies such as full dimensional MIMO (FD-MIMO), array antennas and large-scale antennas, metamaterial-based lenses and antennas for improving coverage of terahertz band signals, high-dimensional space multiplexing technology using orbital angular momentum (OAM), and reconfigurable intelligent surface (RIS), and also full-duplex technologies for increasing frequency efficiency of 6G mobile communication technologies and improving system networks, AI-based communication technologies for implementing system optimization by utilizing satellites and AI from the design stage and internalizing end-to-end AI support functions, and next-generation distributed computing technologies for implementing services at levels of complexity exceeding the limit of UE operation capability by utilizing ultra-high-performance communication and computing resources.

Definitions for other certain words and phrases are provided throughout this patent document. Those of ordinary skill in the art should understand that in many if not most instances, such definitions apply to prior as well as future uses of such defined words and phrases.

### SUMMARY

The present disclosure discloses a method and an apparatus for error correction coding in a communication system, more specifically, to error correction coding integrated with transmission diversity.

In one embodiment, a transmitter apparatus in a communication system is provided. The transmitter apparatus includes an encoder configured to: identify a data word d from a source, and identify a plurality of encoder output subwords x₁, x₂, . . . , xᵣ from the data word d based on an encoder input mapping relation and a plurality of encoding functions, wherein r is greater than one; and a diversity mapper configured to: identify a plurality of channel input subwords v₁, v₂, . . . , vₛ from the plurality of encoder output subwords x₁, x₂, . . . , xᵣ based on a diversity transform and a subchannel assignment relation, and transmit the plurality of channel input subwords v₁, v₂, . . . , vₛ over a channel, wherein the channel comprises a plurality of subchannels, wherein s is related to a number of subchannels and s is greater than one.

In another embodiment, a transmitter method in a communication system is provided. The transmitter method includes an encoding step, wherein the encoding step comprises: identifying a data word d from a source, and identifying a plurality of encoder output subwords x₁, x₂, . . . , xᵣ from the data word d based on an encoder input mapping relation and a plurality of encoding functions, wherein r is greater than one; and a diversity mapping step, wherein the diversity mapping step comprises: identifying a plurality of channel input subwords v₁, v₂, . . . , vₛ from the plurality of encoder output subwords x₁, x₂, . . . , xᵣ based on a diversity transform and a subchannel assignment relation, and transmitting the plurality of channel input subwords v₁, v₂, . . . , vₛ over a channel, wherein the channel comprises a plurality of subchannels, wherein s is related to a number of subchannels and s is greater than one.

In yet another embodiment, a receiver method in a communication system is provided. The receiver method includes a diversity demapping step, wherein the diversity demapping step comprises: receiving a plurality of channel output subwords y₁, y₂, . . . , yₛ from a channel, wherein the channel comprises a plurality of subchannels, wherein s is related to a number of subchannels and s is greater than one, identifying an ith decoder input statistic lᵢ in an ith iteration of a receiver process, wherein the ith decoder input statistic lᵢ is based on y₁, y₂, . . . , yₛ, any decision feedback messages received from a decoder in iterations prior to the ith iteration, and a diversity transform matrix G_{DIV}, wherein G_{DIV} is a r×t matrix with t>r≥2, sending the ith d7ecoder input statistic lᵢ to the decoder, and obtaining an ith decision feedback from the decoder; and a decoding step, wherein the decoding step comprises: obtaining the ith decoder input statistic lᵢ from a diversity demapper, identifying an ith partial decoder decision based on the ith decoder input statistic 1i, wherein the ith partial decoder decision comprises an ith decoded encoder input subword ûᵢ, determining whether an ith termination condition is satisfied, in case that the ith termination condition is not satisfied, identifying an ith decision feedback message and sending the ith decision feedback message to the diversity demapper, wherein the ith decision feedback message is based on the ith partial decoder decision and comprises an ith decoded encoder output subword \hat{x}ᵢ, wherein \hat{x}ᵢ is obtained from the ith decoded encoder input subword ûᵢ based on an ith encoding function, wherein the ith encoding function comprises an N×N polar transform, in case that the termination condition is satisfied, identifying a decoder output and sending the decoder output to a destination, wherein the decoder output comprises a decoded data word d, wherein \hat{d}_{B}_{ᵢ}(ûᵢ)_{D}_{ᵢ} for each 1≤i≤r, wherein (B₁, B₂, . . . , Bᵣ) is a non-trivial partition of {1, 2, . . . , K}, wherein K is the number of elements of \hat{d}, wherein (D₁, D₂, . . . , Dᵣ) is a collection of sets such that Dᵢ⊂{1, 2, . . . , N}, wherein |Dᵢ|= [symbol] |B [symbol] ᵢ| for each 1≤i≤r.

Other technical features may be readily apparent to one skilled in the art from the following figures, descriptions, and claims.

Before undertaking the DETAILED DESCRIPTION below, it may be advantageous to set forth definitions of certain words and phrases used throughout this patent document. The term “couple” and its derivatives refer to any direct or indirect communication between two or more elements, whether or not those elements are in physical contact with one another. The terms “transmit,” “receive,” and “communicate,” as well as derivatives thereof, encompass both direct and indirect communication. The terms “include” and “comprise,” as well as derivatives thereof, mean inclusion without limitation. The term “or” is inclusive, meaning and/or. The phrase “associated with,” as well as derivatives thereof, means to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” means any device, system, or part thereof that controls at least one operation. Such a controller may be implemented in hardware or a combination of hardware and software and/or firmware. The functionality associated with any particular controller may be centralized or distributed, whether locally or remotely. It should be noted that the functionality associated with any particular controller may be centralized or distributed, whether locally or remotely. The phrase “at least one of,” when used with a list of items, means that different combinations of one or more of the listed items may be used, and only one item in the list may be needed. For example, “at least one of A, B, and C” includes any of the following combinations: A, B, C, A and B, A and C, B and C, and A and B and C.

Moreover, various functions described below can be implemented or supported by one or more computer programs, each of which is formed from computer readable program code and embodied in a computer readable medium. The terms “application” and “program” refer to one or more computer programs, software components, sets of instructions, procedures, functions, objects, classes, instances, related data, or a portion thereof adapted for implementation in a suitable computer readable program code. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable memory device.

Definitions for other certain words and phrases are provided throughout this patent document. Those of ordinary skill in the art should understand that in many if not most instances, such definitions apply to prior as well as future uses of such defined words and phrases.

Before undertaking the DETAILED DESCRIPTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, such a device may be implemented in hardware, firmware or software, or some combination of at least two of the same. It should be noted that the functionality associated with any particular controller may be centralized or distributed, whether locally or remotely.

Moreover, various functions described below can be implemented or supported by one or more computer programs, each of which is formed from computer readable program code and embodied in a computer readable medium. The terms “application” and “program” refer to one or more computer programs, software components, sets of instructions, procedures, functions, objects, classes, instances, related data, or a portion thereof adapted for implementation in a suitable computer readable program code. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable memory device.

Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 illustrates an example wireless network in which embodiments of the present principles could be implemented according to certain aspects of the present disclosure;

FIG. 2A illustrates an example user equipment network in which embodiments of the present principles may be implemented according to certain aspects of the present disclosure;

FIG. 2B illustrates an example base station network in which embodiments of the present principles may be implemented according to certain aspects of the present disclosure;

FIG. 3A is a block diagram illustrating a communication system in which embodiments of the present principles may be implemented according to certain aspects of the present disclosure;

FIG. 3B is a flowchart illustrating a transmitter method according to certain aspects of the present disclosure;

FIG. 3C is a flowchart illustrating a refinement of an encoding step in a transmitter method according to certain aspects of the present disclosure;

FIG. 3D is a flowchart illustrating a refinement of a diversity mapping step in a transmitter method according to certain aspects of the present disclosure;

FIG. 3E is a flowchart illustrating a receiver method according to certain aspects of the present disclosure.

FIG. 4 is a display of illustrative examples of rank properties of diversity transforms according to certain aspects of the present disclosure;

FIG. 5 is a diagram illustrating exemplary diversity transforms, families of diversity transform output erasure scenarios, and subchannel assignment partitions according to certain aspects of the present disclosure;

FIG. 6A is a display of configuration parameters for a first embodiment of the present principles;

FIG. 6B is a chart comparing the performance of a first embodiment of the present principles with that of a benchmark polar code.

FIG. 7 is a block diagram of a terminal or UE 700 according to an embodiment of the disclosure.

FIG. 8 is a block diagram of a base station 800 according to an embodiment of the disclosure.

### DETAILED DESCRIPTION

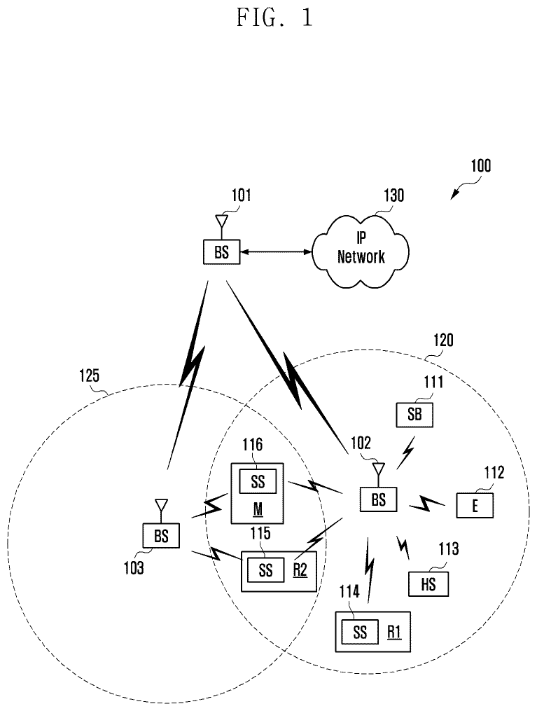

FIGS. 1 through 6B, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged system or device.

In emerging applications such as Ultra Reliable Low Latency Communications (URLLC) there exists a requirement to send relatively short messages with extreme reliability and low latency over wireless channels that are subject to fading and interference as well as additive thermal noise. Conventional methods for providing extreme reliability, such as Automatic Repeat Request (ARQ) and Hybrid-ARQ (HARQ) schemes, are not compatible with the low latency requirement. Hence, there is need for employing error correction coding methods that are integrated with transmission diversity so as to provide extreme reliability without a need for retransmissions. The present principles address this problem by integrating error correction coding with transmission diversity.

The present principles can be used provided that the channel in the system is capable of supporting transmission diversity, such as a channel comprising multiple independently fading subchannels. Given such a channel, the present principles introduce a diversity transform between error correction coding and the channel, providing simple interfaces on the code side and the channel side, so that a given diversity transform can be used with different codes and channels.

A class of codes that are especially well suited for use as part of or in combination with the present principles is polar coding, thanks to the rate- and length-compatible nature of these codes and the availability of low-complexity methods for encoding and decoding them. In one aspect, the present principles may be seen as an extension of polar coding in which a polar transform is extended by a diversity transform using the Kronecker product of the two transforms. Such multi-kernel polar code constructions have been known since the beginning of polar coding [1] and studied extensively, notably in the references [2],[3],[4],[5]. The main focus of the references [1],[2],[3],[4] has been improved performance over discrete memoryless channels. The reference [5] used mix kernels for providing flexible code lengths so that puncturing or shortening can be avoided.

Unlike references [1],[2],[3],[4],[5], the present principles are focused on shielding error correction coding (whether the coding is polar or otherwise) from extreme forms of outage events occurring in the channel. To realize this goal, the present principles introduce redundancy as part of the diversity transform, in effect using the diversity transform as an inner code that can cope with channel outage events; as a result, the present principles rely on strictly rectangular diversity transform matrices. In contrast, previous work on multi-kernel polar codes typically puts the emphasis on performance over memoryless channels, which makes it disadvantageous to use non-square kernel matrices when interfacing with the channel.

Polar coding in the context of fading channels has been studied quite extensively, as in the references [6],[7],[8],[9], which combined polar coding with various types of interleaving, signal shaping, or modulation methods to provide resilience against fading and outage. The present principles differ from this line of work by purposefully avoiding the use of an interleaver. It is well known that interleaving is a practical but suboptimal procedure for dealing with fading. Instead of interleavers, the present principles rely on algebraic constructions that are optimized for rank properties of a diversity transform under various channel outage scenarios. In preferred embodiments of the present principles, the diversity transform is derived from maximum distance separable (MDS) codes, which is a prior art technique for constructing distance-optimal error correcting codes, as described in [10].

### REFERENCES

[1]E. Arikan, “Channel Polarization: A Method for Constructing Capacity-Achieving Codes for Symmetric Binary-Input Memoryless Channels,” IEEE Transactions on Information Theory, vol. 55, no. 7, pp. 3051-3073, July 2009, doi: 10.1109/TIT.2009.2021379.
[2]R. Mori and T. Tanaka, “Non-binary polar codes using Reed-Solomon codes and algebraic geometry codes,” in 2010 IEEE Information Theory Workshop (ITW), IEEE, August 2010, pp. 1-5. doi: 10.1109/CIG.2010.5592755.
[3]N. Presman, O. Shapira, and S. Litsyn, “Mixed-Kernels Constructions of Polar Codes,” IEEE Journal on Selected Areas in Communications, vol. 34, no. 2, pp. 239-253, February 2016, doi: 10.1109/JSAC.2015.2504278.
[4]N. Presman, O. Shapira, S. Litsyn, T. Etzion, and A. Vardy, “Binary Polarization Kernels From Code Decompositions,” IEEE Transactions on Information Theory, vol. 61, no. 5, pp. 2227-2239, May 2015, doi: 10.1109/TIT.2015.2409257.
[5]F. Gabry, V. Bioglio, I. Land, and J. C. Belfiore, “Multi-kernel construction of polar codes,” in 2017 IEEE International Conference on Communications Workshops (ICC Workshops), May 2017, pp. 761-765. doi: 10.1109/ICCW.2017.7962750.
[6]S. R. Tavildar, “An interleaver design for polar codes over slow fading channels,” arXiv:1610.04924 [cs, math], October 2016, Accessed: Oct. 18, 2016. [Online]. Available: http://arxiv.org/abs/1610.04924
[7]T. Koike-Akino, Y. Wang, S. C. Draper, K. Sugihara, and W. Matsumoto, “Bit-interleaved polar-coded OFDM for low-latency M2M wireless communications,” in 2017 IEEE International Conference on Communications (ICC), Paris, France: IEEE, May 2017, pp. 1-7. doi: 10.1109/ICC.2017.7996931.
[8]H. Ju, M. Kim, D. Lee, M. Jang, and S.-H. Kim, “Diversity Guaranteeing Transmission of Polar Codes over Block Fading Channels,” in 2022 IEEE Globecom Workshops, December 2022, pp. 480-485. doi: 10.1109/GCWkshps56602.2022.10008535.
[9]K. Niu and Y. Li, “Polar Coded Diversity on Block Fading Channels Via Polar Spectrum,” IEEE Trans. Signal Process., vol. 69, pp. 4007-4022, 2021, doi: 10.1109/TSP.2021.3094652.
[10]F. J. MacWilliams and N. J. A. Sloane, The Theory of Error Correcting Codes, vol. 16. In North-Holland Mathematical Library, vol. 16. Amsterdam: North-Holland, 1977.
   The above-listed publications are incorporated herein by reference.

Hereinafter, embodiments of the disclosure will be described in detail with reference to the accompanying drawings.

In describing the embodiments, descriptions related to technical contents well-known in the art and not associated directly with the disclosure will be omitted. Such an omission of unnecessary descriptions is intended to prevent obscuring of the main idea of the disclosure and more clearly transfer the main idea.

For the same reason, in the accompanying drawings, some elements may be exaggerated, omitted, or schematically illustrated. Further, the size of each element does not completely reflect the actual size. In the drawings, identical or corresponding elements are provided with identical reference numerals.

The advantages and features of the disclosure and ways to achieve them will be apparent by making reference to embodiments as described below in detail in conjunction with the accompanying drawings. However, the disclosure is not limited to the embodiments set forth below, but may be implemented in various different forms. The following embodiments are provided only to completely disclose the disclosure and inform those skilled in the art of the scope of the disclosure, and the disclosure is defined only by the scope of the appended claims. Throughout the specification, the same or like reference numerals designate the same or like elements. Furthermore, in describing the disclosure, a detailed description of known functions or constitution incorporated herein will be omitted in the case that it is determined that the description may make the subject matter of the disclosure unnecessarily unclear. The terms which will be described below are terms defined in consideration of the functions in the disclosure, and may be different according to users, intentions of the operators, or customs. Therefore, the definitions of the terms should be made based on the contents throughout the specification.

The terms used in the following description to refer to access nodes, network entities, messages, interfaces between network entities, various types of identification information, and the like, are provided merely for the convenience of explanation by way of example. Therefore, the present disclosure is not limited to the terms described below, and other terms having equivalent technical meanings may also be used. Such terms may also be replaced with terms defined in 3GPP Technical Specifications (TS) where appropriate.

In the following description, the terms physical channel and signal may be used interchangeably with data or control signal. For example, the term PDSCH (Physical Downlink Shared Channel) refers to a physical channel through which data is transmitted, but the term PDSCH may also be used to refer to the data itself. That is, in the present disclosure, the expression “transmit a physical channel” may be interpreted as being equivalent to the expression “transmit data or a signal via a physical channel.”

In the present disclosure, higher layer signaling refers to a signaling method in which a signal is transmitted from a base station to a terminal using a downlink data channel of the physical layer, or from the terminal to the base station using an uplink data channel of the physical layer. The higher layer signaling may be understood as RRC (Radio Resource Control) signaling or a MAC (Media Access Control) Control Element (CE).

Hereinafter, a base station is an entity that allocates resources to terminals, and may be at least one of a gNode B, an eNode B, a Node B, a base station (BS), a wireless access unit, a base station controller, and a node on a network. A terminal may include a user equipment (UE), a mobile station (MS), a cellular phone, a smartphone, a computer, or a multimedia system capable of performing communication functions. In the disclosure, a downlink (DL) refers to a radio link through which a base station transmits a signal to a UE, and an uplink (UL) refers to a radio link through which a UE transmits a signal to a base station. Furthermore, hereinafter, LTE or LTE-A systems may be described by way of example, but the embodiments of the disclosure may also be applied to other communication systems having similar technical backgrounds or channel types. Examples of such communication systems may include 5th generation mobile communication technologies (5G, new radio, and NR), 6th generation mobile communication technologies developed beyond LTE-A, and hereinafter, the 5G or 6G may be the concept that covers the exiting LTE, LTE-A, or other similar services. In addition, based on determinations by those skilled in the art, the embodiments of the disclosure may also be applied to other communication systems through some modifications without significantly departing from the scope of the disclosure.

Hereinafter, “A or B” as described in the present disclosure may be understood to include A, or B, or both A and B.

In addition, “at least one of A, B, and C” as described in the present disclosure may be understood to include A, or B, or C, or any combination thereof.

Furthermore, “A/B” as described in the present disclosure may be understood as A and/or B, which may include A, or B, or both A and B.

In the specific embodiments of the present disclosure described below, terms or components included in the disclosure may be expressed in singular or plural form depending on the specific embodiments presented. However, such singular or plural expressions are selected appropriately for convenience of description, and the present disclosure is not limited to a singular or plural number of components. A component expressed in the plural form may be implemented as a single component, and a component expressed in the singular form may be implemented as multiple components.

The drawings or flowcharts described below illustrate exemplary methods that may be implemented according to the principles of the present disclosure, and various modifications may be made to the methods illustrated in the flowcharts of the present disclosure. For example, although illustrated as a series of steps, various steps in each drawing or flowchart may overlap, occur in parallel, occur in a different order, or be repeated. In other examples, any step may be omitted or replaced with another step.

Herein, it will be understood that each block of the flowchart illustrations, and combinations of blocks in the flowchart illustrations, may be performed by computer program instructions. These computer program instructions may be loaded onto a processor of a general purpose computer, special purpose computer, or other programmable data processing apparatus to produce a machine, such that the instructions, which perform through the processor of the computer or other programmable data processing apparatus, create means for performing the functions specified in the flowchart block(s). These computer program instructions may also be stored in a computer usable or computer-readable memory that may direct a computer or other programmable data processing apparatus to function in a particular manner, such that the instructions stored in the computer usable or computer-readable memory produce an article of manufacture including instruction means that perform the function specified in the flowchart block(s). The computer program instructions may also be loaded onto a computer or other programmable data processing apparatus to cause a series of operational steps to be performed on the computer or other programmable data processing apparatus to produce a computer executed process such that the instructions that perform on the computer or other programmable data processing apparatus provide steps for executing the functions specified in the flowchart block(s).

Further, each block may represent a module, segment, or portion of code, which includes one or more executable instructions for executing the specified logical function(s). It should also be noted that in some alternative implementations, the functions noted in the blocks may occur out of the order. For example, two blocks shown in succession may in fact be performed substantially concurrently or the blocks may sometimes be performed in the reverse order, depending upon the functionality involved.

As used in embodiments of the disclosure, the “˜unit” refers to a software element or a hardware element, such as a Field Programmable Gate Array (FPGA) or an Application Specific Integrated Circuit (ASIC), which performs a predetermined function. However, the “˜unit” does not always have a meaning limited to software or hardware. The “˜unit” may be constructed either to be stored in an addressable storage medium or to execute one or more processors. Therefore, the “˜unit” includes, for example, software elements, object-oriented software elements, components such as class elements and task elements, processes, functions, properties, procedures, sub-routines, segments of a program code, drivers, firmware, micro-codes, circuits, data, database, data structures, tables, arrays, and parameters. The components and functions provided by the “˜unit” may be either combined into a smaller number of components and a “˜unit,” or divided into additional components and a “˜unit.” Moreover, the components and “˜units” may be implemented to reproduce one or more CPUs within a device or a security multimedia card. Further, in the embodiments, the “˜unit” may include one or more processors.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a Wi-Fi chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

It will be appreciated that various embodiments of the disclosure according to the claims and description in the specification can be realized in the form of hardware, software or a combination of hardware and software.

Any such software may be stored in non-transitory computer readable storage media. The non-transitory computer readable storage media store one or more computer programs (software modules), the one or more computer programs include computer-executable instructions that, when executed by one or more processors of an electronic device individually or collectively, cause the electronic device to perform a method of the disclosure.

Any such software may be stored in the form of volatile or non-volatile storage such as, for example, a storage device like read only memory (ROM), whether erasable or rewritable or not, or in the form of memory such as, for example, random access memory (RAM), memory chips, device or integrated circuits or on an optically or magnetically readable medium such as, for example, a compact disk (CD), digital versatile disc (DVD), magnetic disk or magnetic tape or the like. It will be appreciated that the storage devices and storage media are various embodiments of non-transitory machine-readable storage that are suitable for storing a computer program or computer programs comprising instructions that, when executed, implement various embodiments of the disclosure. Accordingly, various embodiments provide a program comprising code for implementing apparatus or a method as claimed in any one of the claims of this specification and a non-transitory machine-readable storage storing such a program.

The methods and apparatuses proposed in the embodiments of the present disclosure are not limited to each embodiment individually, but may also be applied in combination of all or some of the embodiments proposed in the disclosure. Therefore, the embodiments of the present disclosure may be modified and applied without significantly departing from the scope of the present disclosure, as would be understood by those skilled in the art. In this case, even if certain wordings are described differently across embodiments, they may be used interchangeably or in combination if their underlying concepts are equivalent. For example, for the same or equivalent concept, even if one embodiment uses the expression “A” and another embodiment uses the expression “B”, such expressions may be understood interchangeably, in substitution, or in combination.

Hereinafter, the operational principle of the present disclosure will be described in detail with reference to the accompanying drawings. In the following description of the present disclosure, detailed descriptions of well-known functions or configurations will be omitted when it is determined that such descriptions may unnecessarily obscure the gist of the present disclosure. Furthermore, the terms described below are defined in consideration of the functions of the present disclosure, and the definitions may vary depending on the user, the operator's intention, or customary practices. Therefore, the definitions should be made based on the overall content of the present specification.

In the following, for brevity, both FDD and TDD are considered as the duplex method for both DL and UL signaling.

Although exemplary descriptions and embodiments to follow assume orthogonal frequency division multiplexing (OFDM) or orthogonal frequency division multiple access (OFDMA), this disclosure can be extended to other OFDM-based transmission waveforms or multiple access schemes such as filtered OFDM (F-OFDM).

The present disclosure covers several components which can be used in conjunction or in combination with one another, or can operate as standalone schemes.

Before we discuss the details of the present principles, we list the basic notation that we will use throughout.

The notation a∈A indicates that a is an element of a set A. For any two sets A and B, the notation A⊂B means that A is a subset of B, i.e., every element of A is an element of B. For any set A, we write A^{c} to denote the complement A in a specified universal set; we write |A| to denote the size (number of elements) of A. (For x a real number, |x| denotes the absolute value of x.) The notation Ø denotes the empty set. A partition of a set S is an ordered collection of sets [symbol] =(A₁, A₂, . . . , Aₙ) such that A₁ ∪A₂ ∪ . . . ∪Aₙ=S and Aᵢ∩Aⱼ=Ø for every 1≤i<j≤n. We will say that a partition [symbol] (A₁, A₂, . . . , Aₙ) is non-trivial if the partition contains at least two non-empty sets; otherwise, we call the partition a trivial partition. Thus, to speak of a non-trivial partition [symbol] =(A₁, A₂, . . . , Aₙ) of a set S, we must have n≥2 and |S|≥2. Note also that we have defined a partition as an ordered collection of sets, since order will be important in the following description.

We use vectors and matrices over algebraic structures (mostly, finite fields) to denote various signals and encoding and decoding operations on signals. Given a vector v=(v₁, v₂, . . . , vₘ) with m components, we say that v has length m, refer to the set {1, 2, . . . , m} as the index set of v, and call vᵢ the ith element or the ith coordinate of v. For any subset A⊂{1, 2, . . . , m} of indices of a vector v, we write v_{A} to denote the subvector v_{A} (vᵢ:i∈A) consisting of elements vᵢ of v with indices in A, with the elements of v listed in increasing index order in v_{A}. For example, for v=(v₁, v₂, . . . , v₈) and A={2,5,3,8,1}, we have v_{A}=(v₁, v₂, v₃, v₅, v₈).

We use capital letters to denote matrices over fields. For example,

$$A = [ \begin{matrix}{a}_{1 , 1} & ⋯ & {a}_{1 , n} \\ ⋮ & ⋱ & ⋮ \\ {a}_{m , 1} & ⋯ & {a}_{m , n}\end{matrix} ]$$

denotes an m×n array or matrix with m rows and n columns and with entry a_{i,j} in the ith row and jth column. For A a matrix, the notation A⁻¹ and A^{T} denote the inverse (if exists) and transpose of A. Given two matrices A and B, AB denotes the product of A and B. Given a vector v and a matrix A, we denote their product by vA. For these products to make sense, the matrices and vectors involved must have compatible dimensions. The Kronecker product of any two matrices

$$A = [ \begin{matrix}{a}_{1 , 1} & ⋯ & {a}_{1 , n} \\ ⋮ & ⋱ & ⋮ \\ {a}_{m , 1} & ⋯ & {a}_{m , n}\end{matrix} ]$$

$$and$$

$$B = [ \begin{matrix}{b}_{1 , 1} & ⋯ & {b}_{1 , t} \\ ⋮ & ⋱ & ⋮ \\ {b}_{s , 1} & ⋯ & {b}_{s , t}\end{matrix} ]$$

is defined as

$$A ⊗ B = [ \begin{matrix}{a}_{1 , 1} B & ⋯ & {a}_{1 , n} B \\ ⋮ & ⋱ & ⋮ \\ {a}_{m , 1} B & ⋯ & {a}_{m , n} B\end{matrix} ] .$$

Often, we consider indexed collections of signals or objects in a system that are not necessarily numerical in nature. In such cases we use the terms “words” and “arrays” to mean one-dimensional and two-dimensional collections. More precisely, the term “word” is used to mean a collection indexed by a single set of integers I, such as I={1, 2, . . . , m}. The term “array” is used to mean a collection indexed by the cartesian product I×J of two sets of integers I and J, such as I={1, 2, . . . m} and J={1, 2, . . . , n}. Words and arrays are denoted by notation similar to vectors and matrices, respectively.

FIG. 1 is a schematic diagram of a wireless network 100 in which embodiments of the present principles may be implemented according to certain aspects of the present disclosure. The wireless network 100 is for illustration only and does not limit the scope of the present disclosure. In particular, the present disclosure can be applied in wireline communication systems as well as wireless systems.

The wireless network 100 includes an eNodeB (eNB) 101, an eNB 102, and an eNB 103. The eNB 101 communicates with the eNB 102 and the eNB 103. The eNB 101 also communicates with at least one Internet Protocol (IP) network 130, such as the Internet, a proprietary IP network, or other data network.

Depending on the network type, other well-known terms may be used instead of “eNodeB” or “eNB,” such as “base station”, “BS”, “gNodeB”, or “access point.” For the sake of convenience, the terms “eNodeB” and “eNB” are used in this patent document to refer to network infrastructure components that provide wireless access to remote terminals. Also, depending on the network type, other well-known terms may be used instead of “user equipment” or “UE,” such as “mobile station” (or “MS”), “subscriber station” (or “SS”), “remote terminal,” “wireless terminal,” or “user device.” For the sake of convenience, the terms “user equipment” and “UE” are used in this patent document to refer to remote wireless equipment that wirelessly accesses an eNB, whether the UE is a mobile device (such as a mobile telephone or smartphone) or is normally considered a stationary device (such as a desktop computer or vending machine).

The eNB 102 provides wireless broadband access to the network 130 for a first plurality of user equipments (UEs) within a coverage area 120 of the eNB 102. The first plurality of UEs includes a UE 111, which may be located in a small business (SB); a UE 112, which may be located in an enterprise (E); a UE 113, which may be located in a WiFi hotspot (HS); a UE 114, which may be located in a first residence (R1); a UE 115, which may be located in a second residence (R2); and a UE 116, which may be a mobile device (M) like a cell phone, a wireless laptop, a wireless personal digital assistant (PDA), tablet, or the like. The eNB 103 provides wireless broadband access to the network 130 for a second plurality of UEs within a coverage area 125 of the eNB 103. The second plurality of UEs includes the UE 115 and the UE 116. In some embodiments, one or more of the eNBs 101-103 may communicate with each other and with the UEs 111-116 using WiFi, WiMAX, 3G, 4G, long-term evolution (LTE), LTE-A, 5G, or other present or future advanced wireless communication techniques.

Dotted lines show the approximate extents of the coverage areas 120 and 125, which are shown as approximately circular for the purposes of illustration and explanation only. It should be clearly understood that the coverage areas associated with eNBs, such as the coverage areas 120 and 125, may have other shapes, including irregular shapes, depending upon the configuration of the eNBs and variations in the radio environment associated with natural and man-made obstructions.

As described in more detail below, one or more of eNB 101, eNB 102 and eNB 103 include 2D antenna arrays that can be used in conjunction with embodiments of the present disclosure. In some embodiments, one or more of eNB 101, eNB 102 and eNB 103 support the codebook design and structure for systems having 2D antenna arrays.

Although FIG. 1 illustrates one example of the wireless network 100, various changes may be made to FIG. 1. For example, the wireless network 100 could include any number of eNBs and any number of UEs in any suitable arrangement. Also, the eNB 101 could communicate directly with any number of UEs and provide those UEs with wireless broadband access to the network 130. Similarly, each eNB 102-103 could communicate directly with the network 130 and provide UEs with direct wireless broadband access to the network 130. Further, the eNB 101, 102, and/or 103 could provide access to other or additional external networks, such as external telephone networks or other types of data networks.

The embodiments of the present principles depicted in the figures and described below may be implemented in an eNB (such as eNB 102) and/or a UE (such as UE 116), as described in further detail below.

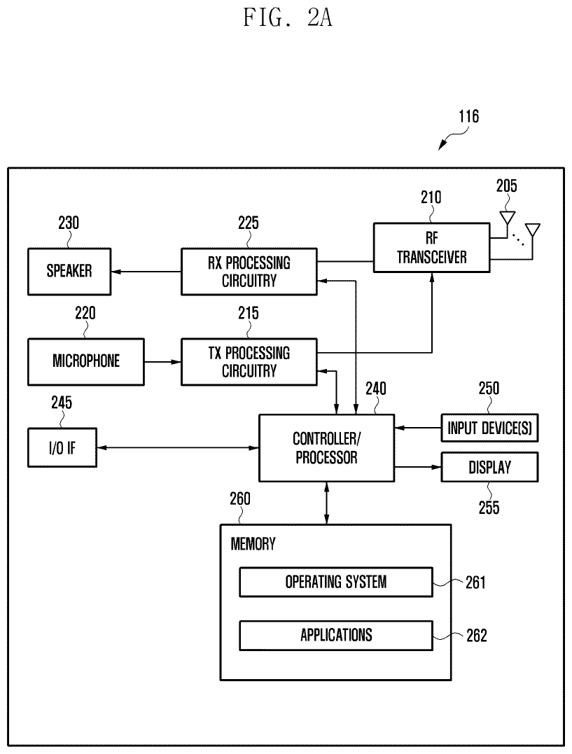

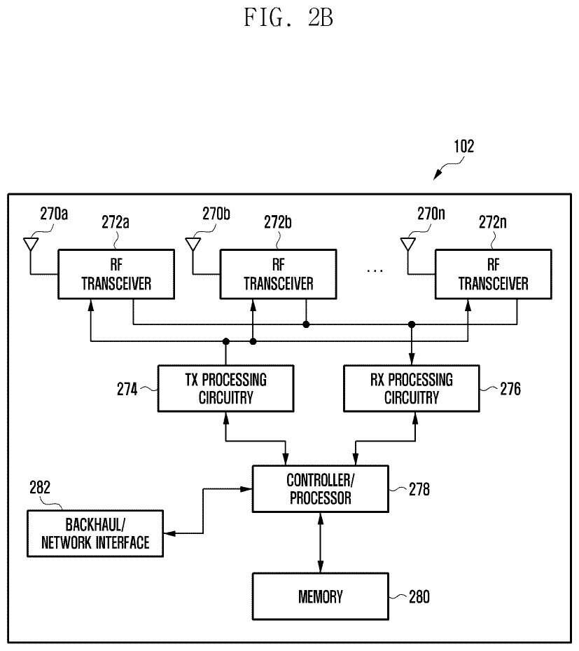

FIG. 2A illustrates an example user equipment network in which embodiments of the present principles may be implemented according to certain aspects of the present disclosure. The embodiment of the UE 116 illustrated in FIG. 2A is for illustration only, and the UEs 111-116 of FIG. 1 could have the same or similar configuration. However, UEs come in a wide variety of configurations, and FIG. 2A does not limit the scope of the present disclosure to any particular implementation of a UE.

The UE 116 includes an antenna 205, a radio frequency (RF) transceiver 210, a transmit (TX) processing circuitry 215, a microphone 220, and a receive (RX) processing circuitry 225. The UE 116 also includes a speaker 230, a controller/processor 240, an input/output (I/O) interface 245, input device(s) 250 (such as a keypad), a display 255, and a memory 260. The memory 260 includes a basic operating system (OS) program 261 and one or more applications 262. Either the OS program 261, one of the applications 262, or some combination thereof may implement programming for employing the present principles as described in the various embodiments herein.

The RF transceiver 210 receives, from the antenna 205, an incoming RF signal transmitted by an eNB of the network 100. The RF transceiver 210 may down-convert the incoming RF signal to generate an intermediate frequency (IF) or baseband signal which would be sent to the RX processing circuitry 225. The RX processing circuitry 225 transmits the processed signal to the speaker 230 (such as for voice data) or to the controller/processor 240 for further processing (such as for web browsing data).

The TX processing circuitry 215 receives, as at least some input data for the source data block, analog or digital voice data from the microphone 220 or other outgoing baseband data (such as web data, e-mail, or interactive video game data) from the controller/processor 240. The RF transceiver 210 receives the outgoing processed baseband or IF signal from the TX processing circuitry 215 and up-converts the baseband or IF signal to an RF signal that is transmitted via the antenna 205.

The controller/processor 240 can include one or more processors or other processing devices and execute the basic OS program 261 stored in the memory 260 in order to control the overall operation of the UE 116. For example, the controller/processor 240 could control the reception of forward channel signals and the transmission of reverse channel signals by the RF transceiver 210, the RX processing circuitry 225, and the TX processing circuitry 215 in accordance with well-known principles. In some embodiments, the controller/processor 240 includes at least one programmable microprocessor or microcontroller, while in other embodiments the main processor includes dedicated circuitry as well as (optionally) programmable logic or processing circuits.

The controller/processor 240 is also capable of executing other processes and programs resident in the memory 260, such as operations for channel quality measurement and reporting for systems having 2D antenna arrays. The controller/processor 240 can move data and/or instructions into or out of the memory 260 as required by an executing process. In some embodiments, the controller/processor 240 is configured to execute the applications 262 based on the OS program 261 or in response to signals received from eNBs or an operator. The controller/processor 240 is also coupled to the I/O interface 245, which provides the UE 116 with the ability to connect to other devices such as laptop computers and handheld computers. The I/O interface 245 is the communication path between these accessories and the controller/controller 240. The controller/processor 240 can be configured to perform the functions performed by the encoder, diversity mapper, decoder, and diversity demapper described in the following description.

The controller/processor 240 is also coupled to the input device(s) 250 (which may simply be a single button or may be an array or other set of buttons) and the display 255. The operator of the UE 116 can use the input device(s) 250 to enter data into the UE 116. The display 255 may be a touch screen display or other display capable of rendering text and/or at least limited graphics, such as from web sites, and receiving touch inputs by a user in accordance with known practices.

The memory 260 is coupled to the controller/processor 240, and at least a part of the memory 260 could include a random access memory (RAM), and another part of the memory 260 could include a Flash memory or other read-only memory (ROM).

Although FIG. 2A illustrates one example of the UE 116, various changes may be made to FIG. 2A. For example, various components in FIG. 2A could be combined, further subdivided, or omitted and additional components could be added according to particular needs. As a particular example, the controller/processor 240 could be divided into multiple processors, such as one or more central processing units (CPUs), one or more application specific integrated circuits (ASICs), one or more field programmable gate arrays (FPGAs), and one or more graphics processing units (GPUs). Also, while FIG. 2A illustrates the UE 116 configured as a mobile telephone or smartphone, UEs could be configured to operate as other types of mobile or stationary devices.

FIG. 2B illustrates an example of an enhanced NodeB (eNB) network in which embodiments of present principles may be implemented according to certain aspects of the present disclosure. The embodiment of the eNB 102 shown in FIG. 2B is for illustration only, and other eNBs of FIG. 1 could have the same or similar configuration. However, eNBs come in a wide variety of configurations, and FIG. 2B does not limit the scope of the present disclosure to any particular implementation of an eNB. It is noted that the eNB 101 and the eNB 103 can include the same or similar structure as the eNB 102.

As shown in FIG. 2B, the eNB 102 includes multiple antennas 270a-270n, multiple RF transceivers 272a-272n, a transmit (TX) processing circuitry 274, and a receive (RX) processing circuitry 276. In certain embodiments, one or more of the multiple antennas 270a-270n include 2D antenna arrays. The eNB 102 also includes a controller/processor 278, a memory 280, and a backhaul or network interface 282.

The RF transceivers 272a-272n receive, from the antennas 270a-270n, incoming RF signals, such as signals transmitted by UEs or other eNBs. The RF transceivers 272a-272n down-convert the incoming RF signals to generate IF or baseband signals. The IF or baseband signals are sent to the RX processing circuitry 276, which generates processed signals by filtering, decoding, and/or digitizing the baseband or IF signals. The RX processing circuitry 276 transmits the processed signals to the controller/processor 278 for further processing.

The TX processing circuitry 274 receives at least some input data. The TX processing circuitry 274 implements circuits to encode, multiplex, and/or digitize the outgoing baseband data to generate processed signals. The RF transceivers 272a-272n receive the outgoing processed signals from the TX processing circuitry 274 and up-converts the baseband or IF signals to RF signals that are transmitted via the antennas 270a-270n.

The controller/processor 278 can include one or more processors or other processing devices that control the overall operation of the eNB 102. For example, the controller/processor 278 could control the reception of forward channel signals and the transmission of reverse channel signals by the RF transceivers 272a-272n, the RX processing circuitry 276, and the TX processing circuitry 274 in accordance with well-known principles. The controller/processor 278 could support additional functions as well, such as more advanced wireless communication functions. Any of a wide variety of other functions could be supported in the eNB 102 by the controller/processor 278. In some embodiments, the controller/processor 278 includes at least one microprocessor or microcontroller, while in other embodiments the main processor includes dedicated circuitry (e.g., for controlling encoding and decoding processes, code puncturing and/or shortening processes, data mapping, etc.) as well as (optionally) programmable logic or processing circuits. The controller/processor 278 can be configured to perform the functions performed by the encoder, diversity mapper, decoder, and diversity demapper described in the following specification.

The controller/processor 278 is also capable of executing programs and other processes resident in the memory 280, such as a basic OS. The controller/processor 278 is also capable of supporting channel quality measurement and reporting for systems having 2D antenna arrays. In some embodiments, the controller/processor 278 supports communications between entities. The controller/processor 278 can move data and/or instructions into or out of the memory 280 as required by an executing process.

The controller/processor 278 is also coupled to the backhaul or network interface 282. The backhaul or network interface 282 allows the eNB 102 to communicate with other devices or systems over a backhaul connection or over a network. The interface 282 could support communications over any suitable wired or wireless connection(s). For example, when the eNB 102 is implemented as part of a cellular communication system (such as one supporting 3G, 4G, 5G, LTE, or LTE-A), the interface 282 could allow the eNB 102 to communicate with other eNBs over a wired or wireless backhaul connection. When the eNB 102 is implemented as an access point, the interface 282 could allow the eNB 102 to communicate over a wired or wireless local area network or over a wired or wireless connection to a larger network (such as the Internet). The interface 282 includes any suitable structure supporting communications over a wired or wireless connection, such as an Ethernet or RF transceiver.

The memory 280 is coupled to the controller/processor 278. Part of the memory 280 could include a RAM, and another part of the memory 280 could include a Flash memory or other ROM. In certain embodiments, a plurality of instructions is stored in memory. The instructions are configured to cause the controller/processor 278 to perform the systematic and/or non-systematic encoding or decoding processes, shortening processes, data mapping, etc.

Although FIG. 2B illustrates one example of the eNB 102, various changes may be made to FIG. 2B. For example, the eNB 102 could include any number of each component shown. As a particular example, an access point could include a number of interfaces 282, and the controller/processor 278 could support routing functions to route data between different network addresses. As another particular example, while shown as including a single instance of the TX processing circuitry 274 and a single instance of the Rx processing circuitry 276, the eNB 102 could include multiple instances of each (such as one per RF transceiver).

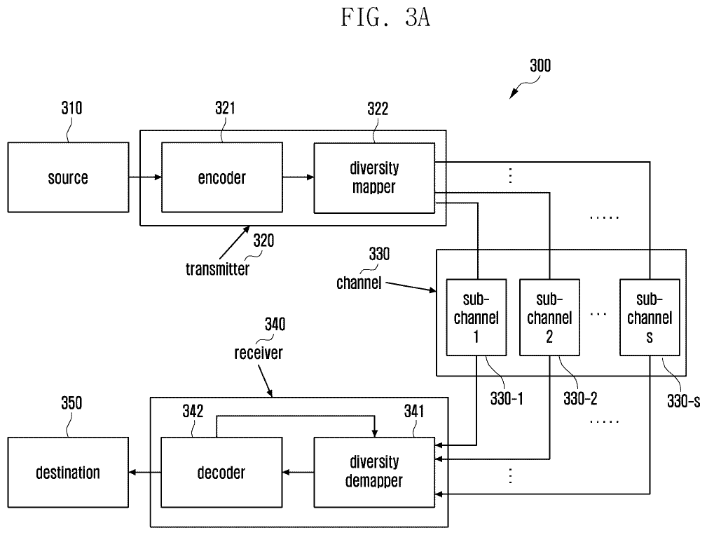

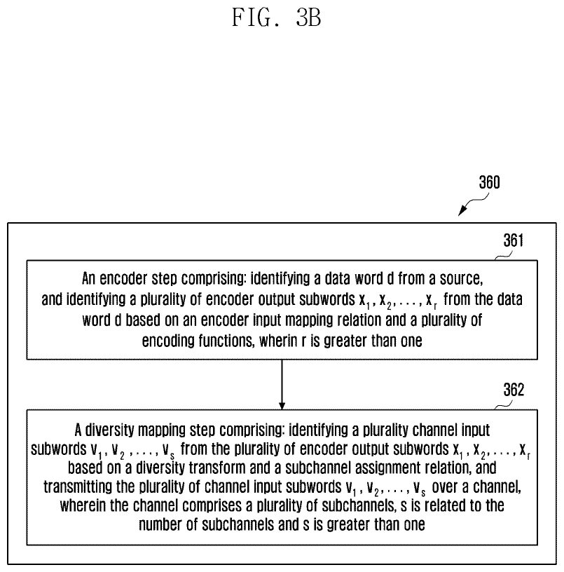

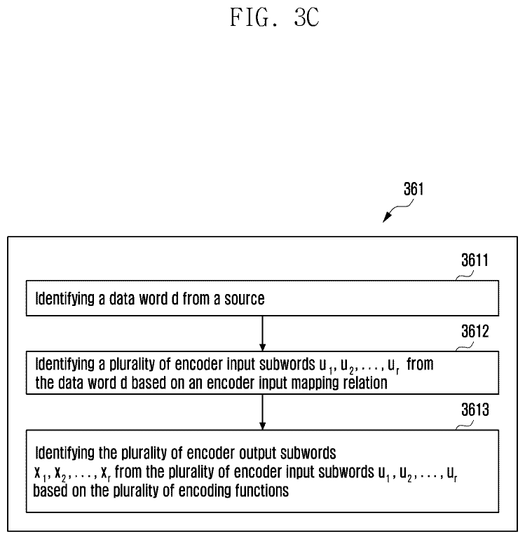

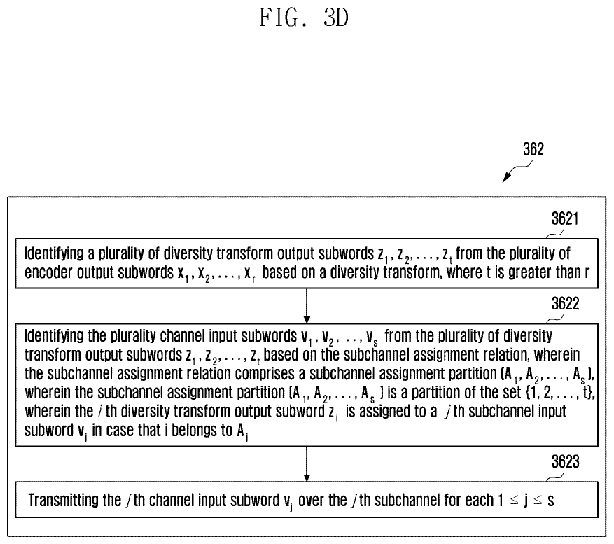

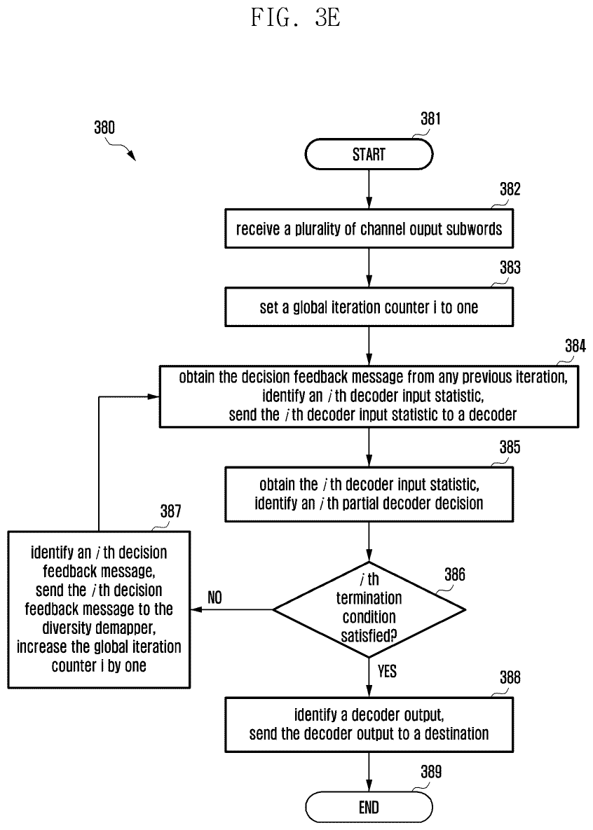

FIG. 3A is a block diagram illustrating a communication system 300 in which embodiments of the present principles may be implemented according to certain aspects of the present disclosure. The system 300 comprises a source 310, a transmitter 320 connected to the source, a channel 330 connected to the transmitter 320, a receiver 340 connected to the channel 330, and a destination 350 connected to the receiver 340. The transmitter 320 comprises an encoder 321 and a diversity mapper 322. The channel 330 comprises a plurality of subchannels 330-1 through 330-s, wherein s is the number of subchannels and s≥2. The receiver 340 comprises a diversity demapper 341 and a decoder 342. The basic goal of the communication system 300 is to deliver data from the source 310 to the destination 350 reliably. The present principles are mainly concerned with the case in which the transmitter 320 and the receiver 340 are designed and operated for achieving extreme reliability by utilizing diversity transmission across the channel 330. We now give a more detailed description of the transmitter 320 and the receiver 340 with reference to FIGS. 3B through 3E. A transmitter can be a base station and a receiver can be a terminal, or vice versa.

FIG. 3B is a flowchart illustrating a transmitter method 360 implemented according to an embodiment of the present disclosure. The transmitter method 360 is implemented at the transmitter 320 and comprises an encoding step 361 and a diversity mapping step 362. The encoding step 361 is executed at the encoder 321 and comprises (i) identifying a data word d from a source, (ii) identifying a plurality of encoder output subwords x₁, x₂, . . . , xᵣ from the data word d based on an encoder input mapping relation and a plurality of encoding functions, wherein r is greater than one. The diversity mapping step 362 is executed at the diversity mapper 322 and comprises (i) identifying a plurality of channel input subwords v₁, v₂, . . . , vₛ from the plurality of encoder output subwords x₁, x₂, . . . , xᵣ based on a diversity transform and a subchannel assignment relation, and (ii) transmitting the plurality of channel input subwords v₁, v₂, . . . , vₛ over a channel, wherein the channel comprises a plurality of subchannels, s is related to the number of subchannels and s is greater than one.

The above flowcharts illustrate example methods that may be implemented in accordance with the principles of the disclosure, and various changes may be made to the methods illustrated in the flowcharts herein. For example, while shown as a series of operations, various operations in each figure may overlap, occur in parallel, occur in a different order, or occur multiple times. In another example, operations may be omitted or replaced by other operations.

FIG. 3C is a flowchart illustrating a refinement of the encoding step 361 in the transmitter method 360 according to certain aspects of the present disclosure. According to FIG. 3C, the encoding step 361 of method 360 further comprises the steps of: 3612 identifying a plurality of encoder input subwords u₁, u₂, . . . , uᵣ from the data word d based on the encoder input mapping relation; and, 3613 identifying the plurality of encoder output subwords x₁, x₂, . . . , xᵣ from the plurality of encoder input subwords u₁, u₂, . . . , uᵣ based on the plurality of encoding functions.

The above flowcharts illustrate example methods that may be implemented in accordance with the principles of the disclosure, and various changes may be made to the methods illustrated in the flowcharts herein. For example, while shown as a series of operations, various operations in each figure may overlap, occur in parallel, occur in a different order, or occur multiple times. In another example, operations may be omitted or replaced by other operations.

In preferred embodiments of the present principles, the ith encoder output subword xᵢ is related to the ith encoder input subword uᵢ by an ith encoding function for each 1≤i≤r, wherein uᵢ has a length Mᵢ which may depend on i, xᵢ has a length N which is independent of i, and N≥Mᵢ≥1 for all 1≤i≤r.

FIG. 3D is a flowchart illustrating a refinement of the diversity mapping step 362 in the transmitter method 360 according to certain aspects of the present disclosure. According to FIG. 3D, the diversity mapping step 362 further comprises the steps of: 3621 identifying a plurality of diversity transform output subwords z₁, z₂, . . . , zₜ from the plurality of encoder output subwords x₁, x₂, . . . , xᵣ based on a diversity transform, where t is greater than r; 3622 identifying the plurality of channel input subwords v₁, v₂, . . . , vₛ from the plurality of diversity transform output subwords z₁, z₂, . . . , zₜ based on the subchannel assignment relation, wherein the subchannel assignment relation comprises a subchannel assignment partition [symbol] (A [symbol] ₁, A₂, . . . , Aₛ), wherein the subchannel assignment partition [symbol] (A [symbol] ₁, A₂, . . . , Aₛ) is a non-trivial partition of the set {1, 2, . . . , t}, wherein the ith diversity transform output subword zᵢ is assigned to the jth subchannel input word vⱼ in case that i belongs to Aⱼ; and, 3623 transmitting the jth channel input subword vⱼ over the jth subchannel for each 1≤j≤s.

The above flowcharts illustrate example methods that may be implemented in accordance with the principles of the disclosure, and various changes may be made to the methods illustrated in the flowcharts herein. For example, while shown as a series of operations, various operations in each figure may overlap, occur in parallel, occur in a different order, or occur multiple times. In another example, operations may be omitted or replaced by other operations.

The present principles are compatible with a broad variety of encoder input mapping relations. To illustrate one, suppose we are given the sizes (M₁, . . . , Mᵣ) of the encoder input subwords [symbol] (u [symbol] ₁, u₂, . . . , uᵣ) as a design constraint. Let the data word d comprise K elements: d=(d₁, d₂, . . . , d_{K}) for some K≥2, where K may also be viewed as a design constraint. An encoder input mapping relation may be specified in terms of a pair ( [symbol] , [symbol] ), where [symbol] =(B₁, B₂, . . . , Bᵣ) is a non-trivial partition of {1, 2, . . . , K} such that |Bᵢ|≤Mᵢ, 1≤i≤r; and, [symbol] =(D₁, D₂, . . . , Dᵣ) is a collection such that Dᵢ⊂{1, 2, . . . , Mᵢ} and |Dᵢ|= [symbol] |B [symbol] ᵢ|, 1≤i≤r. The pair ( [symbol] , [symbol] ) g defines an input mapping relation via (uᵢ)_{D}_{ᵢ}=d_{B}_{ᵢ} for each 1≤i≤r; in words, this encoder input mapping relation copies a subword d_{B}_{ᵢ} of d onto a corresponding subword (uᵢ)_{D}_{ᵢ} of uᵢ for each 1≤i≤r. The skilled person in the art will recognize the critical aspect of the choice of the non-trivial partition [symbol] =(B₁, B₂, . . . , Bᵣ) lies not so much in the composition of the sets (B₁, B₂, . . . , Bᵣ) but in the choice of the cardinalities Kᵢ=|Bᵢ|, 1≤i≤r, subject to the constraint that

$$K = {\sum }_{i = 1}^{r} {K}_{i} ,$$

with 0≤Kᵢ≤Mᵢ and with at least two of the Kᵢ's strictly positive. As regards the choice of [symbol] , the composition of the sets (D₁, D₂, . . . , Dᵣ) is a major design problem that critically affects the performance obtained by the present principles.

The present principles in some of their preferred embodiments comprise polar coding at the encoder 321. When polar coding is used, using an encoder input mapping based on a pair ( [symbol] , [symbol] ) as defined above makes it possible to utilize prior art methods of polar code design. In particular, given a non-trivial partition (B₁, B₂, . . . , Bᵣ), the sets (D₁, D₂, . . . , Dᵣ) can be chosen in accordance with polar code design rules from prior art such as density evolution, or a table listing polar code bit-channels in ascending order of reliability, etc. Below, we will provide a polar code example, where we illustrate this type of encoder input mapping.

At this point, we can explain the reason for imposing the requirement that [symbol] be a non-trivial partition (excluding trivial partitions). If we were to allow a trivial partition in the framework of the present principles, the resulting system would have no diversity and would be equivalent to a prior art system. Trivial partitions (that yield the parameter choices r=t=s=1) become a better choice than non-trivial partitions (that yield parameter choices 2≤r≤t) when there is no fading in the channel or fading is rare enough that the fading can be tolerated within the specified reliability requirements. The benefits of the present principles emerge when there is need for providing extreme reliability that requires being prepared for various types of outage events.

A second example for an encoder input mapping relation is to map subwords d_{B}_{ᵢ} to subwords (xᵢ)_{D}_{ᵢ} of xᵢ for each 1≤i≤r. For this, it suffices to replace the condition Dᵢ ⊂{1, 2, . . . Mᵢ} with Dᵢ⊂{1, 2, . . . , N}. This type of encoder input mapping rule is systematic in the sense that the data subwords appear transparently as part of the encoder output subwords. Thus, the present principles are compatible with and can take advantage of benefits of systematic encoding.

The system 300 is configured so that the numerical parameters r, t, and s satisfy t>r>1 and t≥s>1. Each encoder input subword may contain, in addition to data symbols from the data word d, frozen symbols and parity symbols. Frozen symbols are fixed to predetermined values. Parity symbols are computed dynamically as functions of the data word d. It is also possible that the data word d contains built-in redundancies such as cyclic redundancy check (CRC) symbols.

If some embodiments of the present principles, the communication system could be configured with multiple encoder input mapping relations and/or multiple subchannel assignment relations in order to provide flexibility with respect to code rate, code length, and degree of diversity. Such multi-configuration systems are common in current wireless standards such as 5G and are one of the requirements of future 6G standard. When the present principles are employed with such multiple configurations, a problem of coordination arises between the transmitter and receiver. In some cases, the receiver may employ blind detection methods to discover the configuration at the transmitter. Alternatively, encoder input mapping relation candidates (relation-1, relation-2, and relation-3) are configured by transmitting a radio resource control (RRC) message, and one relation (say, relation-2) may be specified by transmitting medium access control (MAC) control element (CE) or downlink control information (DCI) (or L1 signaling). Similarly, if we can use multiple sub-channel assignment methods, then we can use same scheme for diversity mapping step. For example, given (or predefined or preconfigured) a number of diversity mapping methods (method -1, method -2 and method -3), one relation (say, method-2) may be specified by transmitting at least one of a corresponding RRC message or DCI. As another example, diversity mapping methods (method -1, method -2 and method -3) are configured by transmitting the RRC message, and one method (say, method-2) may be specified by transmitting at least one of MAC CE or DCI. Furthermore, one of the relations could be to omit diversity transmission for backward compatibility or transmission without diversity.

In the transmitter and receiver, one or more parameters related to at least one of an encoder input mapping relation configuration, a plurality of encoding functions, a diversity transform method, and a subchannel assignment relation configuration may be obtained. Some of the one or more parameters may be predetermined, some may be signaled between the transmitter and receiver, and some may be determined by the transmitter and/or receiver itself. It is also possible that a set including the above parameters is set in advance, and signaling indicating a specific parameter set is transmitted between the transmitter and receiver.

The present principles offer a wide range of implementation choices in a flexible manner thanks to a modular architecture in which the diversity transform is added as a module between various legacy error correction coding methods and the channel. The present and envisioned future wireless standards are equipped with control channels and signaling methods to coordinate a transmitter and receiver to take advantage of the present principles in rapidly changing wireless transmission environments.

Below, we will provide more details about specific design methods for the transmitter 320; however, we now turn our attention back to FIG. 3A and continue our general discussion of the system 300 with a focus on the channel 330 and the receiver 340.

The channel 330 produces a plurality of channel output subwords y₁, y₂, . . . , yₛ in response to the plurality of channel input subwords v₁, v₂, . . . , vₛ. In particular, the ith subchannel 330-i produces an ith channel output subword yᵢ in response to the ith channel input subword vᵢ, 1≤i≤s. The internal details of the channel 330 lie outside the scope of the present principles. The transmitter 320 and the receiver 340 need not know the internal details of the channel 330. Present principles can be applied using a statistical model of the channel 330. In the statistical model, the plurality of channel output subwords y₁, y₂, . . . , yₛ may be one-dimensional or multi-dimensional real- or complex-valued symbols or signals from discrete or continuous alphabets; or they may be probability distributions, or arrays of likelihood ratios or log-likelihood ratios, etc. Additionally, y₁, y₂, . . . , yₛ may comprise various forms of side information about the plurality of subchannels 330-1 through 330-s, such as estimates of fading coefficients, outage events, received signal strengths, SNR estimates, etc.; the present principles are designed to take full advantage of such side information about the channel state.

We now turn to the receiver 340 and outline its general characteristics. The present principles rely on an iterative receiver process at the receiver 340 through the interaction of the diversity demapper 341 and the decoder 342 over a series of iterations. The process comprises four major steps: initialization, diversity demapping, decoding, and termination. Initialization comprises receiving the plurality of channel output subwords from the channel 330. Diversity demapping and decoding steps comprise an iterative loop. Termination comprises producing a receiver output and sending the output to the destination 350. There are several possible ways to implement the details of this type of iterative receiver process. We illustrate a basic implementation next.

FIG. 3E is a flowchart illustrating a receiver method 380 according to certain aspects of the present disclosure. The receiver method 380 is implemented at the receiver 340 and comprises a plurality of steps 381 through 389, where steps 382 through 384 are implemented at the diversity demapper 342; steps 385 through 388 are implemented at the decoder 342; steps 381 and 389 indicate start and end states for the receiver method as a whole.

Initiation of the process: The process starts in step 381 and moves to step 382 when new channel data arrives. In step 382, the diversity demapper 341 receives the plurality of channel output subwords y₁, y₂, . . . , yₛ from the channel 330. In step 383, the diversity demapper 341 initializes the value of a global iteration counter i to 1. The global iteration counter i has global visibility in the sense that its value is visible to both the diversity demapper 341 and the decoder 342 as they execute the steps of the method 380.

Iterative process at the diversity demapper 341: At the outset of an ith iteration, in step 384, the diversity demapper 341 obtains a feedback message sent by the decoder 342 as part of the previous iteration; in the first iteration, there will be no decision feedback message, so the diversity demapper proceeds without attempting to obtain a decision feedback in the first iteration. While still in step 384, the diversity demapper identifies an ith decoder input statistic lᵢ based on the initially received plurality of channel output subwords and any decision feedback received from the decoder 342 in previous iterations, sends the ith decoder input statistic lᵢ to the decoder 342, and starts waiting for an ith decision feedback from the decoder 342.

Iterative process at the decoder 342: In step 385, the decoder 342 obtains the ith decoder input statistic lᵢ and identifies an ith partial decoder decision. In step 386, the decoder 342 checks if an ith termination condition is satisfied. If the termination condition is not satisfied, then the decoder 342 executes step 387 which comprises identifying an ith decision feedback message, sending the ith decision feedback message to the diversity demapper 341, and increasing the global iteration counter by one. At this point, the ith iteration is completed, and the next iteration begins in step 384, with the diversity demapper taking control of the process.

Completion of the process: When the termination condition in step 386 is satisfied, the decoder 342 proceeds to step 388, which comprises identifying a decoder output and sending the decoder output to the destination 350. The next step 389 marks the end of the receiver process. The process may return to step 381 and initiate a new receiver process.

We now provide further details on possible implementations of various steps of the receiver method 380. In a basic embodiment of the receiver method 380, the ith partial decoder decision may comprise an ith decoded encoder input subword ûᵢ and the ith decision feedback message may comprise an ith decoded encoder output subword \hat{x}ᵢ. Then, the steps 385 and 387 are regarded successful if ûᵢ and \hat{x}ᵢ replicate the true values uᵢ and xᵢ of the ith encoder input and output subwords, respectively. The ith termination condition in step 386 may comprise checking if value of the global iteration counter i is less than r, the number of encoder input subwords. The ith termination condition in step 386 may further comprise checking for a decoding failure, e.g., by checking if ûᵢ satisfies a cyclic redundancy check. If step 388 is reached without a detected decoder failure, then the decoder output may comprise a decoded data word \hat{d}, wherein \hat{d} is identified from the plurality of decoded encoder input subwords ûᵢ, û₂, . . . , ûᵣ by using an inverse of the encoder input mapping rule (that is used at the transmitter 320). Otherwise, if step 388 is reached with a detected decoder failure, the decoder 342 may send an error code to the destination to indicate a decoder failure. As for the diversity demapping steps of a basic embodiment, the ith decoder input statistic lᵢ may comprise a conditional probability distribution on possible values of the ith encoder output subword xᵢ given the plurality of channel output subwords y₁, y₂, . . . , yₛ and the first (i−1) decoded encoder output subwords \hat{x}₁, \hat{x}₂, . . . , \hat{x}ᵢ₋₁ received from the decoder 342 in preceding iterations. (In the first iteration, \hat{x}₁, \hat{x}₂, . . . , \hat{x}ᵢ₋₁ is to be interpreted as an empty list of subwords.) Below, we give some simulation results for this type of basic receiver and provide exact specifications of each step of the receiver method 380.

The above basic embodiment of the receiver method 380 is serial in the sense that the embodiment takes r iterations to produce a decoded data \hat{d}. Serial receiver implementations minimize hardware complexity at the expense of latency. The receiver method 380 as depicted in the flowchart is general enough to accommodate parallelized implementations, in which the diversity demapper 341 and the decoder 342 collaborate to produce multiple partial decoder decisions per iteration, and complete the receiver process in a smaller number of iterations. Such parallel implementations cut down latency at the expense of hardware complexity. As the person skilled in the art will recognize, there are many ways of implementing the receiver method 380 in parallel in accordance with the flowchart in FIG. 3E. One straightforward alternative is to employ multiple copies of a serial implementation of the receiver method 380 in parallel, with each copy configured to produce the plurality of decoded encoder input subwords û₁, û₂, . . . , ûᵣ in various different orders u_{π(1)}, u_{π(2)}, . . . , u_{π(r)} as determined by various different permutations π of the index set {1, 2, . . . , r}. In such implementations, the parallel copies of the serial receiver processes may pool their partial decoder decisions and decision feedback messages so as to help each other. The parallel decoding process terminates as soon as reliable estimates are available for each member of the plurality of encoder input subwords u₁, u₂, . . . , uᵣ.

Clearly, the above type of parallel decoder process is highly complex to implement; however, if implemented properly, the process may reduce latency and improve performance (reduce the probability of decoding error) because the process uses diversity in decoding (in addition to transmission diversity). Parallel decoding could be selected to reduce latency and improve performance when there are symmetries built into the diversity transform and various decoding orders are equivalent to each other under these symmetries. In another variant of implementing a parallel receiver process in accordance with the receiver method 380, one may use an adaptive decoding order in which a plurality of copies of the receiver method 380 choose a set of decoding order permutations adaptively after observing the plurality of channel output subwords y₁, y₂, . . . , yₛ. Adaptive decoding methods would prioritize permutations that are more likely to succeed and could improve performance or reduce cost of implementation. The present principles set a framework for exploiting diversity in transmission, which in turn sets the stage for employing a rich set of ideas for taking advantage of diversity. The scope of the present principles covers all such variants of the receiver method 380 that will be obvious to the person skilled in the art after the description given here.

The above flowcharts illustrate example methods that may be implemented in accordance with the principles of the disclosure, and various changes may be made to the methods illustrated in the flowcharts herein. For example, while shown as a series of operations, various operations in each figure may overlap, occur in parallel, occur in a different order, or occur multiple times. In another example, operations may be omitted or replaced by other operations.

We omitted describing common control functions that are necessary for orderly execution of the steps of the flowchart in FIG. 3E in order not to clutter the description with unnecessary detail. Such details will be obvious to the person skilled in the art.

We now turn our focus to preferred embodiments of the present principles and describe specific encoding and decoding methods. To that end, we will consider a mathematical formulation of the present principles using standard vector space and probability theory concepts. The mathematical formulation is intended to illustrate the present principles in a clear and precise manner; they should not be interpreted as limiting the scope of the present principles in any manner.

We begin the mathematical formulation with the transmitter 320. We will use vectors and matrices to represent signal processing steps in the transmitter 320. We will use row vectors to represent signals (words or subwords) and matrices to represent operations on signals. We will represent the plurality of encoder input subwords u₁, u₂, . . . , uᵣ, the plurality of encoder output subwords x₁, x₂, . . . , xᵣ, and the plurality of diversity transform output subwords z₁, z₂, . . . , zₜ as row vectors. For the sake of simplicity in presentation, we will assume that the vectors for x₁, x₂, . . . , xᵣ and z₁, z₂, . . . , zₜ have a common length N. We allow the vector for uᵢ to have a length Mᵢ that may depend on i, 1≤i≤r. Under this assumption about the lengths, we will have the vector representations uᵢ=(u_{i,1}, u_{i,2}, . . . , u_{i,M}_{ᵢ}), xⱼ=(x_{j,1}, x_{j,2}, . . . , x_{j,N}), and zₖ=(z_{k,1}, z_{k,2}, . . . , z_{k,N}), for i=1, . . . , r, j=1, . . . , r, k=1, . . . , t. In preferred embodiments of the present principles, the length parameters satisfy N≥Mᵢ≥0 for all 1≤i≤r. The sum of the lengths of the plurality of encoder input subwords u₁, u₂, . . . , uᵣ, namely

$${\sum }_{i = 1}^{r} {M}_{i} ,$$

must be large enough to accommodate all the elements of the input data word d. If u₁, u₂, . . . , uᵣ and the data input word d are over a common alphabet, e.g., if they are all binary vectors, then we must have

$${\sum }_{i = 1}^{r} {M}_{i} \geq K ,$$

where K denotes the length of the input data word d. Even when u₁, u₂, . . . , uᵣ and d are over the same alphabet, the present principles allow having

$${\sum }_{i = 1}^{r} {M}_{i} > K$$

since there may be additional symbols, such as frozen symbols or parity-symbols, inserted into the encoder input subwords.

In preferred embodiments of the present principles, the encoding and diversity transform operations are linear operations represented by matrices. We represent the ith encoding function that maps the ith encoder input uᵢ to the ith encoder output xᵢ by a Mᵢ×N matrix G⁽ⁱ⁾, and refer to the ith encoding function as an ith encoding matrix, 1≤i≤r. We represent the diversity transform by a r×t matrix G_{DIV} and refer to the diversity transform as a diversity transform matrix.

In preferred embodiments, the encoder 321 is configured to identify the ith encoder output subword xᵢ from the ith encoder input subword uᵢ by computing

$${x}_{i , j} = {\sum }_{k = 1}^{{M}_{i}} {u}_{i , k} {g}_{k , j}^{( i )} ,$$

$$where$$

$${g}_{k , j}^{( i )}$$

denotes the (k,j)th element of G⁽ⁱ⁾, or equivalently, by computing xᵢ=uᵢG⁽ⁱ⁾, 1≤i≤r.

In preferred embodiments, the diversity mapper 322 is configured to identify the plurality of diversity transform output subwords z₁, z₂, . . . , zₜ from the plurality of encoder output subwords x₁, x₂, . . . , xₜ by computing

$${z}_{j , n} = {\sum }_{i = 1}^{r} {g}_{i , j}^{DIV} {x}_{i , n} , 1 \leq j \leq t , 1 \leq n \leq N ,$$

where

$${g}_{i , j}^{DIV}$$

denotes the (i,j)th entry of the diversity transform matrix G_{DIV}. An equivalent form of the diversity transform is

$${z}^{n} = {G}_{DIV}^{T} {x}^{n} ,$$

where xⁿ=(x_{1,n}, x_{2,n}, . . . , x_{r,n})^{T} and zⁿ=(z_{1,n}, z_{2,n}, . . . z_{t,n})^{T}, 1≤n≤N; or, compactly,

$$Z = {G}_{DIV}^{T} X ,$$

where

$$X = [ \begin{matrix}{x}_{1 , 1} & {x}_{1 , 2} & ⋯ & {x}_{1 , N} \\ {x}_{2 , 1} & {x}_{2 , 2} & ⋯ & {x}_{2 , N} \\ ⋮ & ⋮ & ⋱ & ⋮ \\ {x}_{r , 1} & {x}_{r , 2} & ⋯ & {x}_{r , N}\end{matrix} ]$$

is an encoder output array and

$$Z = [ \begin{matrix}{z}_{1 , 1} & {z}_{1 , 2} & ⋯ & {z}_{1 , N} \\ {z}_{2 , 1} & {z}_{2 , 2} & ⋯ & {z}_{2 , N} \\ ⋮ & ⋮ & ⋱ & ⋮ \\ {z}_{t , 1} & {z}_{t , 2} & ⋯ & {z}_{t , N}\end{matrix} ]$$

is a diversity transform output array. We notice that the ith rows of X and Z are equal to xᵢ and zᵢ, respectively; and the nth columns of X and Z are equal to xn and Zn, respectively. From an implementation viewpoint, the diversity transform

$$Z = {G}_{DIV}^{T} X$$

comprises N independent diversity transforms

$${z}^{n} = {G}_{DIV}^{T} {x}^{n} , 1 \leq n \leq N ,$$

which can be computed in parallel or semi-parallel fashion to reduce latency (at the expense of increased hardware complexity).

The diversity mapper 322 further comprises a subchannel assignment relation, which in turn comprises a subchannel assignment partition [symbol] =(A₁, A₂, . . . , Aₛ) as described above. The diversity mapper 322 assigns (multiplexes) a kth diversity transform output subword zₖ into an ith channel input subword vᵢ (and thereby transmits zₖ over the ith subchannel 330-i) if and only if k∈Aᵢ, 1≤i≤s and 1≤k≤t. Thus, for each 1≤i≤s, the ith channel input subword vᵢ comprises the elements {z_{k,j}:k∈Aᵢ,j=1, . . . , N} in some arbitrary order. An outage event occurring in the ith subchannel 330-i erases all diversity transform output subwords zₖ whose indices k belong to Aᵢ. Inside vᵢ, the payload {zₖ:k∈Aᵢ} of vᵢ may be serialized in any desired order. For example, one may have vᵢ=(zₖ_{_{1,1}}, . . . , Zₖ_{_{a,1}}, zₖ_{_{1, 2}}, . . . , zₖ_{ₐ}_{,2}, . . . , zₖ_{₁}_{,N}, . . . , zₖ_{ₐ}_{,N}), where a=|Aᵢ| and k₁<k₂< . . . <kₐ are the list of all elements of Aᵢ written in increasing index order. There may be benefits to using serializations that are customized to various modulation schemes (as in bit-interleaved coded modulation) that better mitigate the effects of interference and/or fading within the ith subchannel 330-i. The present principles are completely flexible in this regard; they can be used in combination with any serialization method or interleaver.

We turn now to a more precise mathematical formulation of the receiver 340. The receiver 340 decodes the plurality of channel output subwords y₁, y₂, . . . , yₛ and identifies a decoded data word \hat{d} in accordance with a probabilistic model of the communication system 300. The probabilistic model treats the signals (words, subwords) as samples (realization values) of random variables or vectors over various ensembles of possible values. Following convention, we denote samples (realizations) with small case letters and the corresponding random variables, vectors, words, or subwords with capital letters. For example, X₁, . . . , Xₜ denote the random subwords that correspond to x₁, . . . , xₜ. Likewise, Z₁, . . . , Zₜ, V₁, . . . , Vₛ, and Y₁, . . . , Yₛ are the random subwords that correspond to z₁, . . . , zₜ, v₁, . . . , vₛ, and y₁, . . . , yₛ, respectively. We denote probability mass functions and probability density functions using standard notation, e.g., P_{(B|A)(b|a)} denotes the conditional probability of the event {B=b} given the event {A=a}. Sometimes, we write p(b|a) instead of p_{(B|A)(b|a)} when the random ensembles A and B are clear from the context.

An important part of the probabilistic model at the receiver 340 is a channel transition probability function p(Y₁, . . . , Yₛ|V₁, . . . , Vₛ)(y₁, . . . , yₛ|v₁, . . . , vₛ) which denotes the probability mass or the probability density that the plurality of channel output words y₁, . . . , yₛ are received given that the plurality of channel input subwords are v₁, . . . , vₛ are transmitted. A particularly important channel model from the perspective of the present principles is a block-fading channel model. We will discuss this model below when we present some simulation results.

A critical task in receiver implementation is the specification and computation of the plurality of decoder input statistics lᵢ, . . . , lᵣ at the diversity demapper 341. Here, one may follow various well-established general procedures for receiver design. For example, lᵢ may comprise the conditional probability p(Xᵢ|Y₁, . . . , Yₛ, X₁, . . . Xᵢ₋₁)(xᵢ|y₁, . . . , yₛ, \hat{x}₁, . . . , \hat{x}ᵢ₋₁) of possible values of the ith encoder output subword xᵢ given the channel outputs subwords y₁, . . . , yₛ and the hypothesis that all previous decoder decisions are correct: (\hat{x}₁, . . . , \hat{x}ᵢ₋₁)=(x₁, . . . , xᵢ₋₁). This type of lᵢ is suitable when the receiver 340 employs successive cancellation decoding. The present principles may also be implemented so that lᵢ comprises likelihood ratios or log-likelihood ratios, which may improve the numerical stability of computations. Various approximations may be introduced into the computation of lᵢ to reduce computational complexity or keep numerical stability under control. The person skilled in the art will have no difficulty in adapting such methods for computing soft channel information to the problem here. The scope of the present principles covers all such methods for calculating decoder input statistics.

In general, computation of lᵢ may be a formidable problem due to the size of the ensembles involved. Such difficulties are significantly alleviated if the channel 330 can be modeled using a product-form probability distribution. One type of channel for which the computational problem becomes manageable is a block-fading channel model and that type of channel will be considered in the examples below.

This completes the description of the system 300. It will be clear to the person skilled in the art that the present principles have an architecture that separates the error correction functions and the diversity mapping functions from each other; the two functions can be implemented independently so as to interact with each other over a standardized interface. This makes it possible to use a given diversity mapper/demapper pair in combination with many different types of encoder/decoder pairs. This property is important in adaptive coding schemes where the code lengths and rates can be changed from one use of the system 300 to another.

Two important subjects still require further discussion for implementing various preferred embodiments of the present principles: first, polar coding as a specific FEC scheme in connection with the present principles; and second, specific diversity transforms that provide the promised high reliability transmission. We will begin with the diversity transforms due to their central role in configuring the rest of the system 300.

We now describe various methods for design and performance analysis of diversity transforms. The goal is to find a suitable diversity transform that matches the error correction characteristics of a forward error correcting code, as embodied by the encoder 321 and the decoder 342, to the characteristics of the channel 330. For purposes of diversity transform design and analysis, we consider the diversity mapper 322, the channel 330, and the diversity demapper 341 in isolation from the rest of the system 300 and focus on one-shot transmission scenarios without any error correction coding. The diversity mapper 322 is configured with a diversity transform and a subchannel assignment partition [symbol] =(A₁, . . . , Aₛ), wherein the diversity transform is represented by a r×t matrix G_{DIV} over an arbitrary finite field GF(q). Let the one-shot scenario consist of (i) choosing a vector α=(α₁, . . . , αᵣ)∈GF(q)^{r} at random as a diversity transform input, (ii) mapping α into a diversity transform output β=(β₁, . . . , βₜ)∈GF(q)^{t} by applying the diversity transform β=αG_{DIV}, (iii) mapping β into a plurality of subchannel inputs γ=(γ₁, . . . , γₛ) in accordance with the partition [symbol] and (iv) sending y over the channel 330, with γᵢ over the ith subchannel 330-i.

For purposes of diversity mapper design and performance assessment, we choose to model the channel 330 as an erasure channel. Specifically, we model the ith subchannel 330-i, 1≤i≤s, as a block-erasure channel that either delivers the input γᵢ without any error with some probability 1−ϵ, or erases γᵢ with probability ϵ, where 0≤ϵ≤1 is a block-erasure probability.

We are concerned with extreme scenarios where multiple subchannels suffer block-erasures. We specify such scenarios by sets S⊂{1, 2, . . . , s} that indicate the indices of subchannels that suffer block-erasures. Henceforth, we refer to such sets S as subchannel erasure scenarios. Given a subchannel erasure scenario S, an ith subchannel erases its input if and only if i∈S. We also consider families of subchannel erasure scenarios, such as [symbol] ={S_1, S_2, . . . , S_m}, where each Sⱼ⊂{1, 2, . . . , s} is a specific subchannel erasure scenario, 1≤j≤m. We use the term “subchannel outage” synonymously with “subchannel erasure”.

Erasure of a part γₛ=(γᵢ:i∈S) of the channel input y under a subchannel erasure scenario S induces an erasure of a part β_{E}=(βᵢ:i∈E) of the transform output β, where E is the union of all partition elements Aₖ with k∈S. Thus, the subchannel assignment partition [symbol] =(A₁, . . . , Aₛ) links each subchannel erasure scenario S⊂{1, 2, . . . , s} to a diversity transform output erasure scenario E⊂{1, 2, . . . , t}, where E=U_{k∈S} Aₖ. Likewise, [symbol] links each family of [symbol] subchannel erasure scenarios [symbol] ={S_1, S_2, . . . , S_m} to a family of diversity transform output erasure scenarios ε={E_1, E_2, . . . , E_m}, where Eⱼ=U_{k∈S} Aₖ, 1≤j≤m.

Given a diversity transform output erasure scenario E, the diversity demapper 341 has available only the set of equations β_{E}_{^{c}}=αG_{DIV}(E^{c}) instead of the full set of equations β=αG_{DIV}, wherein E^{c} denotes the complement of E in {1, 2, . . . , t} and G_{DIV}(E^{c}) denotes the matrix obtained from G_{DIV} by deleting all columns of G_{DIV} whose indices belong to E. By an elementary fact from linear algebra, the diversity demapper 341 can recover the unknown a from this reduced set of equations if and only if the matrix G_{DIV} (E^{c}) has full-rank, i.e., rank(G_{DIV} (E^{c}))=r. We state this observation as a diversity transform design criterion.

Full-rank criterion. We say that a pair (G_{DIV},ε), comprising a diversity transform and a family of diversity transform output erasure scenarios, satisfies the full-rank criterion if the matrix G_{DIV}(E^{c}) is a full-rank matrix for each E∈ε.

The family of diversity transform output erasure scenarios ε depends on the family of subchannel erasure scenarios [symbol] and the subchannel assignment partition [symbol] Given a diversity transform G_{DIV} and a family of subchannel erasure scenarios [symbol] , one may try various subchannel assignment partitions [symbol] until a family of diversity transform output erasure scenarios ε is found such that the pair (G_{DIV},ε) satisfies the full-rank criterion. Thus, an important feature of the present principles is the condition that the diversity transform G_{DIV} and a family of diversity transform output erasure scenarios ε={E_1, E_2, . . . , E_m} satisfy the full-rank criterion, wherein ε is related to a family of subchannel erasure scenarios [symbol] , wherein each element of [symbol] comprises an outage of at least one subchannel among the plurality of subchannels.

From the standpoint of the present principles, it is desirable to use a pair (G_{DIV},ε) that satisfies the full-rank criterion. However, the present principles can be used even if no pair (G_{DIV},ε) can be found that satisfies the full-rank criterion. A more fine-grained design criterion, which we call “rank profile”, can be used for studying how the full-rank criterion fails and the severity of failure, and choosing a design accordingly. To describe the rank profile of a given pair (G_{DIV},ε), it will be convenient to introduce some more notation. Let G_{DIV} be an arbitrary r×t diversity transform matrix and let

$${G}_{DIV}^{j} , 1 \leq j \leq r ,$$

denote the (r−j+1)×t matrix obtained from G_{DIV} by deleting the first (j−1) rows of G_{DIV}. Thus,

$${G}_{DIV}^{1} = {G}_{DIV} and {G}_{DIV}^{j}$$

consists of rows j through r of G_{DIV}, in the same order as in G_{DIV}.

Rank profile. Given a pair (G_{DIV},ε) with a r×t diversity transform G_{DIV} and a family of diversity transform output erasure scenarios ε{E₁, . . . , Eₘ}, we define the rank profile matrix R of (G_{DIV},ε) as a m×r matrix whose (i,j)th entry r_{i,j} equals the rank of

$${G}_{DIV}^{j} ( {E}_{i}^{c} ) , i . e . , {r}_{i , j} = rank ( {G}_{DIV}^{j} ( {E}_{i}^{c} ) ) , 1 \leq i \leq m , 1 \leq j \leq r .$$

We refer to the ith row of the rank profile matrix R as the rank profile with respect to the ith erasure pattern Eᵢ.

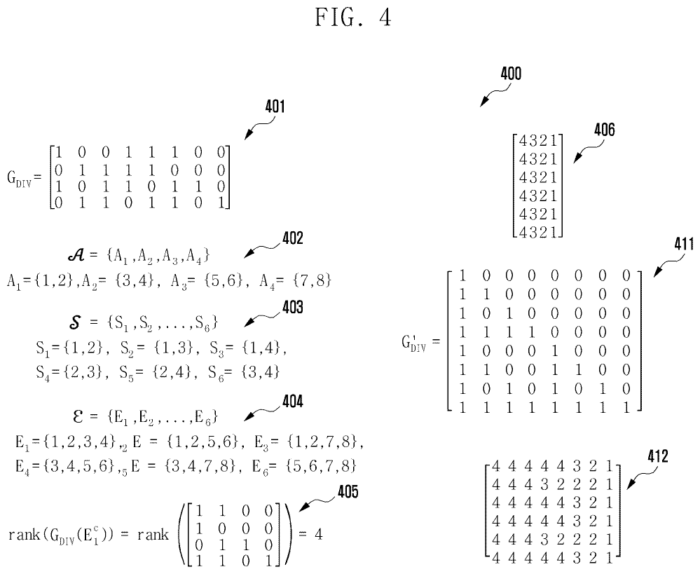

To illustrate the above definitions and discuss their significance, we turn to examples. FIG. 4 is a display 400 of illustrative examples of rank properties of diversity transforms according to certain aspects of the present disclosure. A first illustrative example in the display 400 comprises a first diversity transform G_{DIV} 401, a subchannel assignment partition 402, and a family of subchannel erasure scenarios 403. The first diversity transform 401 has dimensions r=4, t=8, and is intended to be used on a channel 330 with s=4 subchannels under the family of subchannel erasure scenarios 403. Using the notation for the above one-shot transmission scenarios, according to the subchannel assignment partition 402, the plurality of subchannel inputs is given by γᵢ=(β₂ᵢ₋₁,β₂ᵢ), 1≤i≤s=4; so, the family of diversity transform output erasure scenarios are obtained as shown in 404. As shown in 405, we have rank

$$( {G}_{DIV} ( {E}_{1}^{c} ) ) = 4.$$

Similar calculations show that rank

$$( {G}_{DIV} ( {E}_{i}^{c} ) ) = 4$$

for all 1≤i≤6. Thus, the first diversity transform 401 satisfies the full-rank criterion. The rank profile matrix of the first diversity transform 401 is shown in 406. The rank profile matrix shows that each input coordinate of the first diversity transform 401 is fully protected against the family of diversity transform output erasure scenarios 404.

A second illustrative example in the display 400 comprises a second diversity transform

$${G}_{DIV}^{′}$$

411, together with the subchannel assignment partition 402, the family of subchannel erasure scenarios 403, and the family of diversity transform output erasure scenarios 404. In this case, the full-rank criterion fails since the rank under erasures is still 4 but the number of rows is 8. The rank profile matrix for the second diversity transform 411 is shown in 412. The rank profile matrix 412 reveals that under the erasure scenarios E₁, E₃, E₄, E₆, only the transform input components 5, 6, 7, 8 can be recovered; while under the erasure scenarios E₂ and E₅, only the transform input components 3, 4, 7, 8 can be recovered. Thus, if the second diversity transform 411 is used, reliable recovery under all erasure patterns can be guaranteed only for the transform input components 7 and 8; the remaining 6 components must be frozen. The person skilled in the art of polar coding will readily verify that the second diversity transform 411 is a polar transform of order 3 over the binary field:

$${G}_{DIV}^{′} = {F}^{⊗} , where F = [ \begin{matrix}1 & 0 \\ 1 & 1\end{matrix} ] .$$

The matrix F⊗ acts as a diversity transform for ordinary polar codes of length N≥8. The fact that F⊗ has no 4×8 submatrix that satisfies the full-rank condition with respect to the family of subchannel erasure scenarios 403 is a source of weakness that the present principles remedy by using a diversity transform that satisfies the full-rank condition.

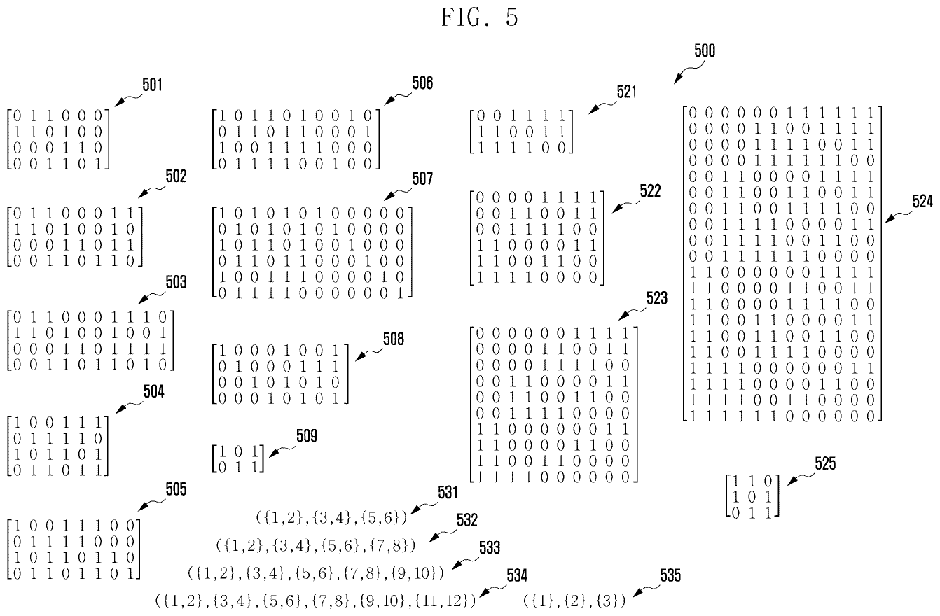

A preferred method of diversity transform construction. A preferred method for constructing diversity transforms is to begin with maximum distance separable (MDS) code constructions and adapt them to the present principles. To illustrate this, we turn to FIG. 5, which is a diagram 500 illustrating exemplary diversity transforms 501 through 509, families of diversity transform output erasure scenarios 521 through 525, and subchannel assignment partitions 531 through 535 according to certain aspects of the present disclosure.

In FIG. 5, we represent diversity transform output erasure scenarios using matrices instead of sets; this gives a more compact representation. For example, the matrix 521 represents a family ε={E₁, E₂, E₃} of diversity transform output erasure scenarios, where the first row of 521 encodes the first scenario E₁={1,2}, the second row of 521 encodes the second scenario E₂={3,4}, and the third row of 521 encodes the third scenario E₃={5,6}. The encoding rule is: j∈Eⱼ if the (i,j)th entry of the matrix 521 equals 0. In FIG. 5, we also used a more compact notation to denote the subchannel assignment partitions. For example, the partition ({1,2}, {3,4}, {5,6}} shown in 531 in full notation could be written as [symbol] =(A₁, A₂, A₃), with A₁={1,2}, A₂={3,4}, A₃={5,6}.

The diversity transforms 501 through 509 are constructed based on Reed-Solomon (RS) codes or their extended versions. In the following, the notation RS(n,k,d) designates an RS code of block length n, dimension k, and minimum distance d. It is a well-known fact that over any field GF(q), there exist RS(n,k,d) codes for any 1≤k≤n≤q−1 and d=n−k+1. RS codes are MDS codes in the sense that for a given n and k, they meet the Plotkin bound d≤n−k+1 with equality. In the following, we also consider (singly, doubly, or triply) extended versions of RS codes, which are also MDS codes.

The diversity transforms 501 through 508 are constructed from generator matrices of RS codes over GF(4). The field GF(4) that we use here is based on a primitive element α∈GF(4) satisfying α²+α+1=0, and has elements {0,1,α,α²=1+α}. The construction comprises converting GF(4)-valued RS generator matrix G_{RS} to a GF(2)-valued diversity transform matrix G_{DIV} by replacing each entry

$${g}_{i , j}^{RS}$$

of G_{RS} with

$$ϕ ( {g}_{i , j}^{RS} ) ,$$

where ϕ: GF(4)→GF(2)^{2×2} is a mapping from GF(4) to the set of 2×2 matrices over GF(2). The specific mapping we use in the examples 501 through 508 is defined as

$$ϕ ( 0 ) = [ \begin{matrix}0 & 0 \\ 0 & 0\end{matrix} ] , ϕ ( 1 ) = [ \begin{matrix}1 & 0 \\ 0 & 1\end{matrix} ] , ϕ ( α ) = [ \begin{matrix}0 & 1 \\ 1 & 1\end{matrix} ] , and ϕ ( α {2}^{} ) = [ \begin{matrix}1 & 1 \\ 1 & 0\end{matrix} ] .$$

If G_{RS} is a k×t matrix over GF(4), then the resulting diversity transform matrix G_{DIV} is a (2k)×(2n) matrix over GF(2).

The mapping ϕ is actually a representation of GF(4) by 2×2 matrices over GF(2) in the sense that ϕ(a+b)=ϕ(a)+ϕ(b) and ϕ(ab)=ϕ(a)ϕ(b) for any a, b∈GF(4). Such field representations exist in general. For any finite field GF(p^{m}) and any 1≤m′≤m, there exists a representation ϕ of GF(p^{m}) using m′×m′ matrices over GF(p^{m-m′+1}). For a method of constructing such matrix representations, we refer to p. 106 of “F. J. MacWilliams and N. J. A. Sloane, The Theory of Error Correcting Codes, vol. 16. in North-Holland Mathematical Library, vol. 16. Amsterdam: North-Holland, 1977”. Thus, the specific diversity transform constructions that we present below to illustrate the present principles over a binary field GF(2) are applicable far more generally to diversity transform constructions over larger fields.

As a first example of the construction, we consider the diversity transform 501. The diversity transform 501 is obtained from the generator matrix

$$[ \begin{matrix}α & 1 & 0 \\ 0 & α & 1\end{matrix} ]$$

of a RS(3,2,2) code over GF(4) by replacing each entry of the generator matrix with the image of that entry under the above mapping ϕ. Note that the diversity transform 501 has 4 rows and 6 columns, which are twice the number of rows and columns of the preceding generator matrix, respectively. It can be verified that diversity transform 501 satisfies the full-rank criterion under the erasure scenario 521. So, the diversity transform 501 together with the subchannel assignment partition 531 provide full protection against any single subchannel outage in a channel 330 with three subchannels.

The diversity transform 502 is obtained from the generator matrix

$$[ \begin{matrix}α & 1 & 0 & {α}^{2} \\ 0 & α & 1 & {α}^{2}\end{matrix} ]$$

of a singly-extended RS(4,2,3) code by replacing each element of the generator matrix by its image under the mapping ϕ. The diversity transform 502 satisfies the full-rank criterion under the erasure scenario 522. So, the diversity transform 502 together with the subchannel assignment partition 532 provide full protection against any two subchannel outages in a channel 330 with four subchannels.

The diversity transform 503 is obtained from the generator matrix

$$[ \begin{matrix}α & 1 & 0 & {α}^{2} & 1 \\ 0 & α & 1 & {α}^{2} & {α}^{2}\end{matrix} ]$$

of a doubly-extended RS(5,2,4) by replacing each element of the generator matrix by its image under the mapping ϕ. The diversity transform 503 satisfies the full-rank criterion under the erasure scenario 523. So, diversity transform 503 together with the subchannel assignment partition 533 provide full protection against any three subchannel outages in a channel 330 with 5 subchannels.

The RS codes used in the construction of the diversity transforms 502 and 503 were obtained by extending a cyclic RS(3,2,2) code. It is possible to begin with a different generator matrix for the RS(3,2,2) code and extend the generator matrix to obtain new diversity transforms that also satisfy the full-rank criterion. The diversity transforms 504, 505, 506, and 507 are obtained in this manner.

The diversity transform 504 is obtained from the generator matrix

$$[ \begin{matrix}1 & α & {α}^{2} \\ 1 & {α}^{2} & α\end{matrix} ]$$

of a RS(3,2,2) code by converting the generator matrix using the representation ϕ. The diversity transform 504 satisfies the full-rank criterion under the erasure scenario 521. The diversity transform 504 and the subchannel assignment partition 531 provide full protection against any single subchannel outage in a channel 330 with 3 subchannels.

The diversity transform 505 is obtained from the generator matrix

$$[ \begin{matrix}1 & α & {α}^{2} & 0 \\ 1 & {α}^{2} & α & 1\end{matrix} ]$$

of a singly-extended RS(4,2,3) code using the representation ϕ. The diversity transform 505 satisfies the full-rank criterion under the erasure scenario 522. The diversity transform 505 and the subchannel assignment partition 532 provide full protection against any two subchannel outages in a channel 330 with 4 subchannels.

The diversity transform 506 is obtained from the generator matrix

$$[ \begin{matrix}1 & {α}^{2} & α & 0 & 1 \\ 1 & α & {α}^{2} & 1 & 0\end{matrix} ]$$

of a doubly-extended RS(5,2,4) code using the representation ϕ. The diversity transform 506 satisfies the full-rank criterion under the erasure scenario 523. The diversity transform 506 and the subchannel assignment partition 533 provide full protection against any three subchannel outages in a channel 330 with 5 subchannels.

The diversity transform 507 is obtained from the generator matrix

$$[ \begin{matrix}1 & 1 & 1 & 1 & 0 & 0 \\ 1 & {α}^{2} & α & 0 & 1 & 0 \\ 1 & α & {α}^{2} & 0 & 0 & 1\end{matrix} ]$$

of a triply-extended RS(6,3,4) code using the representation ϕ. The diversity transform 507 satisfies the full-rank criterion under the erasure scenario 524. The diversity transform 507 and the subchannel assignment partition 534 provide full protection against any three subchannel outages in a channel 330 with 6 subchannels.

The diversity transform 508 is obtained by turning the diversity transform 502 into systematic form through elementary row operations. The diversity transform 508 satisfies the full-rank criterion under the erasure scenario 522. The diversity transform 508 and the subchannel assignment partition 532 provide full protection against any two subchannel outages in a channel 330 with 4 subchannels.

The diversity transform 509 is based on a single parity check code over GF(2) of length 3, dimension 2, and minimum distance 2. The diversity transform 509 satisfies the full-rank criterion under the erasure scenario 525. The diversity transform 509 and the subchannel assignment partition 535 provide full protection against any single subchannel outage in a channel 330 with 3 subchannels. We note that single-parity check codes are MDS codes. The construction here can be generalized by considering single-parity check codes of dimension r≥2, length t=r+1, and distance d=2 over GF(2) or larger fields.

To summarize, we have shown how to construct full-rank diversity transforms starting from RS codes and their extensions. We have restricted our attention to relatively small diversity transforms since we anticipate that these will be the most practical ones due to complexity considerations. For a general r×t diversity transform G_{DIV} over GF(q), the complexity of demapping the channel output (in other words, computing probabilities such as P(Xᵢ|Y₁, . . . , Yₛ, X₁, . . . , Xᵢ₋₁)(xᵢ|y₁, . . . , yₛ, \hat{x}₁, . . . , \hat{x}ᵢ₋₁)) to provide the decoder 342 with decoder input statistics is an order O(q^{r}) operation. So, we expect the present principles to be most useful when the size of the diversity transform is still manageable within practical constraints. In this regard, it is significant that major practical advantages have been observed, as we will show below, in simulation studies using a diversity transform over GF(2) with transform size r=4 and t=8.

Present principles with polar codes. We now return to FIG. 3 and discuss in detail how polar codes can be implemented as part of the system 300. We use the term polar code broadly as any error correcting code whose encoding comprises a polar transform G_{POL}, which is given by a Kronecker product G_{POL}=F₁⊗F₂⊗ . . . ⊗Fₙ of a plurality of (not necessarily identical) kernel matrices Fᵢ over a finite field GF(q), where Fᵢ is a Nᵢ×Nᵢ square matrix with Nᵢ≥2 for all 1≤i≤n. Thus, the polar transform G_{POL} is represented as a N×N square matrix with N=N₁N₂ . . . Nₙ. The description below applies to general types of polar codes in this broad sense. When such a polar code is used, the encoder input subwords uᵢ have a common length Mᵢ=N and the plurality of encoding functions comprises a common ith encoding matrix G⁽ⁱ⁾=G_{POL} for all 1≤i≤r.

In the case of polar codes, the encoder 321 receives the data word d, maps the data word d into a plurality of encoder input subwords u₁, u₂, . . . , uᵣ based on an encoder input mapping relation, and encodes u₁, u₂, . . . , uᵣ into the plurality of encoder output subwords x₁, x₂, . . . , xᵣ by computing x=uᵢG_{POL}, wherein uᵢ=(u_{i,1}, u_{i,2}, . . . , u_{i,N}), (x_{i,1}, x_{i,2}, . . . , x_{i,N}), 1≤i≤r, and wherein the encoder input mapping relation comprises setting (uᵢ)_{D}_{ᵢ}=d_{B}_{ᵢ} for each 1≤i≤r, wherein (B₁, B₂, . . . , Bᵣ) is a non-trivial partition of {1, 2, . . . , K} wherein K is the number of elements of d, wherein (D₁, D₂, . . . , Dᵣ) is a collection of sets such that Dᵢ⊂{1, 2, . . . , Mᵢ}, wherein |Dᵢ|= [symbol] |B [symbol] ᵢ| for each 1≤i≤r, wherein G⁽ⁱ⁾ is a polar transform matrix and Dᵢ is chosen based on a polar code design relation, wherein the polar code design relation comprises a ranking of the reliabilities of the elements of uᵢ, wherein 1≤i≤r. The reliability ranking may be based on a polar code design method such as density evolution customized to given channels or universal design methods such as the 5G NR polar code bit-selection method, which may be stored in a look-up table.

We suppose that the diversity mapper 322 is agnostic to polar coding and follows the general principles as already discussed above. The combined polar transform and diversity transform operations can be expressed as

$${z}_{i , j} = {\sum }_{k = 1}^{r} {\sum }_{l = 1}^{N} {u}_{k , l} {g}_{k , i}^{DIV} {g}_{i , j}^{POL} ,$$

for 1≤i≤r, 1≤j≤N, wherein

$${g}_{k , i}^{DIV}$$

denotes the (k,i)th element of the diversity transform matrix G_{DIV} and

$${g}_{l , j}^{POL}$$

denotes the (l,j)th element of the polar transform matrix G_{POL}.

The polar transform can be written more compactly as X=UG_{POL}, where X is the encoder output array defined earlier and U is a polar transform input array defined as

$$U = [ \begin{matrix}{u}_{1 , 1} & {u}_{1 , 2} & … & {u}_{1 , N} \\ {u}_{2 , 1} & {u}_{2 , 2} & … & {u}_{2 , N} \\ ⋮ & ⋮ & ⋱ & ⋮ \\ {u}_{r , 1} & {u}_{r , 2} & … & {u}_{r , N}\end{matrix} ] .$$

Recalling that the diversity transform can be expressed as

$$Z = {G}_{DIV}^{T} X ,$$

we may write the overall operation as

$$Z = {G}_{DIV}^{T} {UG}_{POL} .$$

The product

$$Z = {G}_{DIV}^{T} {UG}_{POL}$$

can be computed as

$$Z = {G}_{DIV}^{T} ( {UG}_{POL} )$$

as done in FIG. 3 or as

$$Z = ( G {}_{DIV}^{T} U ) {G}_{POL} ,$$

which reverses the order of the transforms. The first way of computing involves r polar transforms followed by N diversity transforms, while the second way requires N diversity transforms followed by t polar transforms. Since t>r by assumption, the first way is preferable from a complexity viewpoint. The first way also offers flexibility since that way allows implementation of the diversity transform without modifying an existing polar encoder, allowing to insert the diversity transform between the encoder 321 and the channel 330. This flexibility is essential in case the polar encoder is inaccessible from outside, e.g., by virtue of being implemented as part of a custom-design integrated circuit.

The person familiar with Elias' product codes and Kronecker products of matrices will recognize that the matrix equation

$$Z = {G}_{DIV}^{T} {UG}_{POL}$$

can be written as z=u [symbol] (G) [symbol] _{POL⊗G}_{_{DIV}}) where z and u are column-by-column vectorizations of the matrices Z and U, [symbol] respectively. To be specific, z=(z_{1,1}, z_{2,1}, z_{r,1}, z_{1,2}, . . . , z_{r,2}, . . . , z_{r,t}) and u=(u_{1,1}, u_{2,1}, . . . u_{r,1}, u_{1,2}, . . . , u_{r,2}, . . . , u_{r,t}). From this perspective, the combination of the polar and diversity transforms is equivalent to a linear code generated by a generator matrix G_{PD}-G_{POL⊗G}_{_{DIV}}. The generator matrix G_{PD} is a Nr×Nt matrix, which is not a square matrix since the present principles require that r<t. Thus, the code with the generator matrix G_{PD} differs from ordinary polar codes that use square polar transforms. The differences between the present principles and prior art polar coding methods in this regard have been discussed already in the BACKGROUND section.

Polar coding is compatible with the receiver method 380 discussed in FIG. 3E. Given the ith decoder input statistic lᵢ, the decoder 342 may be a type of polar decoding algorithm that computes the ith decoded encoder input subword ûᵢ and sends \hat{x}ᵢ=ûᵢG_{POL} back to the diversity demapper 341. The polar decoding algorithm may be a successive cancellation (SC) decoding algorithm, or a variant of SC decoding, such as CRC-aided SC decoding or CRC-aided SC list decoding. There are no limitations to the type of polar decoding algorithm that can be used to implement the decoder 342 in connection with the present principles. Polar coding algorithms with parallelized decoding, automorphism-group decoding, etc., are fully compatible with the general framework of the receiver method 380.

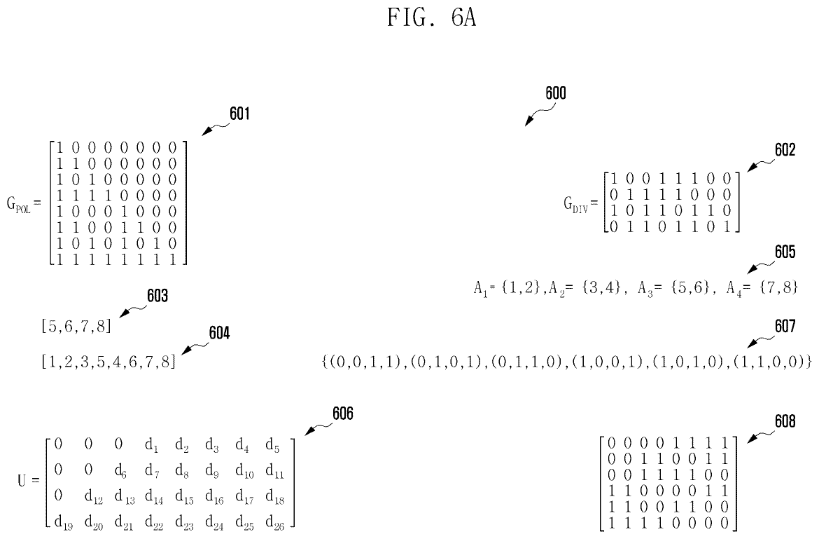

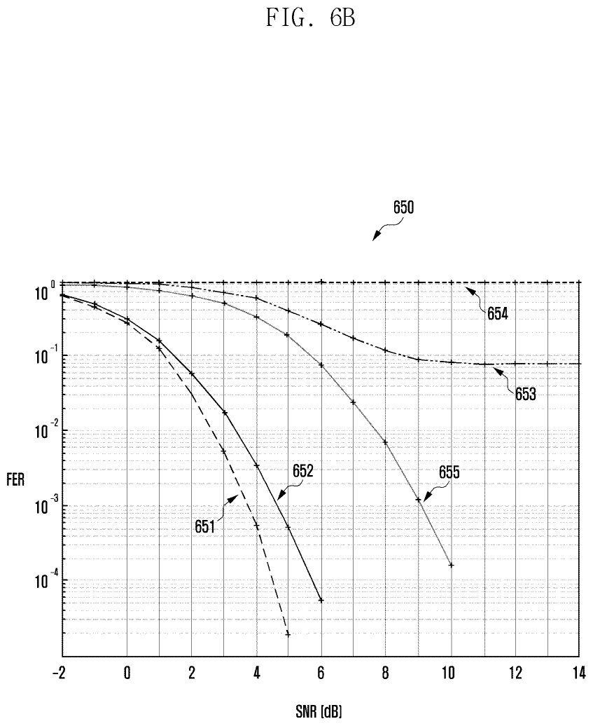

We now turn to some examples to demonstrate the practical utility of the present principles. FIG. 6A is a display 600 of configuration parameters for a first embodiment of the present principles, wherein the parameters 600 comprise a polar transform matrix 601, a diversity transform matrix 602, a payload allocation vector 603, a symbol quality ranking vector 604, and a subchannel assignment partition 605. The polar transform matrix 601 is a standard polar transform of length N=8, with

$${G}_{POL} = {F}^{⊗ n} , F = [ \begin{matrix}1 & 0 \\ 1 & 1\end{matrix} ] ,$$

and n=3. The diversity transform matrix 602 has dimensions r×t with r=4 and t=8; and the diversity transform matrix 602 is the same as the diversity transform matrix 505 discussed above in connection with FIG. 5. The first embodiment is configured to carry a data word d=(d₁, . . . , d_{K}) with length K=26. Thus, the overall code rate in the first embodiment is

$$R = \frac{K}{Nt} = \frac{26}{64} .$$

(In general, the rate of the combined polar-diversity code is given by

$$R = \frac{K}{Nt} ,$$

which equals the product of an average rate

$${R}_{P O L} = \frac{K}{N r}$$

for polar coding and a rate

$${R}_{DIV} = \frac{r}{t}$$

for the diversity transform.)

The encoder 321 in the first embodiment maps the data word d to the plurality of encoder input subwords u₁, u₂, u₃, u₄ in accordance with the payload allocation vector 603 and the symbol quality ranking vector 604. The ith element of the payload allocation vector 603 indicates the number of elements of the data word d that are assigned to the ith encoder input subword uᵢ, 1≤i≤4; accordingly, in the first embodiment, the subwords u₁, u₂, u₃, u₄ receive 5,6,7,8 elements from the data word d, respectively. The elements of the symbol quality ranking vector 604 indicate a ranking of the coordinates of the encoder input subword, with 1 indicating the least preferred position and 8 the most preferred one. In accordance with these rules, the encoder 321 in the first embodiment prepares the polar transform input matrix U as shown by 606. The first row of the polar transform input matrix U 606 is obtained as uᵢ=(0,0,0, d₁, d₂, d₃, d₄, d₅), which is a vector containing a payload of 5 data elements from the data word d as dictated by the first entry of the payload allocation vector 603. The 5 data elements in u₁ are positioned in the top 5 most preferred (highest quality) positions as indicated by the symbol quality ranking vector 604. Thus, the two vectors 603 and 604, together with the number K=26 of the elements of the data word d define a subset of K data positions inside the matrix U 606 that are occupied by the elements of d. In the first embodiment, the elements of d are distributed to the K data positions inside U 606 in an increasing index order starting with the first row and from left to right in each row. This type of distribution is a natural one; however, the present principles are fully compatible with any other distribution order of the elements of the data word d among the K data positions inside the matrix U 606. This statement is true not only for the first embodiment 600 but more generally.

The polar transform and diversity transform operations in the first embodiment 600 are carried out in accordance with the general principles described in detail previously. In particular, the diversity mapper assigns the plurality of diversity transform output subwords z₁, z₂, . . . , zₜ₌₈ into the plurality of channel input subwords v₁, v₂, . . . , vₛ₌₄ in accordance with the subchannel assignment partition 605; so, the diversity transform output subword pairs (z₁, z₂), (z₃, z₄), (z₅, z₆), (z₇, z₈) are assigned, respectively, to the channel input subwords v₁, v₂, v₃, v₄. We use a natural serialization in the first embodiment, so that v_{i,2j-1}=z_{2-1,j} and v_{i,2j}=z_{2i,j} for 1≤i≤s and 1≤j≤N. Thus, the ith channel input subword vᵢ comprises 2N=16 components, vᵢ=(v_{i,1}, v_{i,2}, . . . , v_{i,2N}), 1≤i≤s. The diversity mapper 322 in the first embodiment completes the transmitter 320 operations by transmitting the plurality of channel input subwords v₁, . . . , v_{S} over the channel 330.

The channel 330 in the first embodiment comprises s=4 subchannels and is characterized by the channel transition probability function

$$p ( {y}_{1} … , {y}_{4} \vert {v}_{1} , … , {v}_{4} ) = {\sum }_{h} p ( h ) {\prod }_{i}^{s} p ( {y}_{i} \vert {v}_{i} , {h}_{i} ) ,$$

wherein h=(h₁, h₂, h₃, h₄) is a vector of block-fading coefficients, wherein hᵢ is an ith subchannel block-fading coefficient, 1≤i≤s. Furthermore, we assume that the output of the ith subchannel is related to its input by yᵢ=hᵢξᵢ+wᵢ, wherein ξᵢ is a modulation word corresponding to vᵢ, and wᵢ is an ith subchannel noise word, 1≤i≤s.

We assume that binary phase shift keying (BPSK) modulation is used on all subchannels so that ξᵢ has 2N=16 components, ξᵢ=(ξ_{i,1}, . . . , ξ_{i,2N}), wherein ξ_{i,j}, equals +1 or −1 depending on whether v_{i,j} equals 0 or 1, respectively, 1≤i≤s=4, 1≤j≤2N=16. With BPSK modulation, each subchannel carries one bit per use of the subchannel, so a block of transmission takes 2N=16 uses of each subchannel. The fading coefficient hᵢ stays fixed for the entire block of 2N uses of the ith subchannel. The ith noise word wᵢ comprises 2N=16 components wᵢ=(w_{i,1}, . . . , w_{i,2N}) and we assume that the components are statistically independent Gaussian random variables with mean 0 and variance σ². Under these modeling assumptions, we have

$$p ( {y}_{i} \vert {ξ}_{i} , {h}_{i} ) = {\prod }_{j = 1}^{2 N ( = 16 )} \frac{1}{\sqrt{2 π {σ}^{2}}} exp ( - \frac{{( y {i , j}_{} - {h}_{i} {ξ}_{i , j} )}^{2}}{2 {σ}^{2}} ) .$$

Thus, conditional on the value of hᵢ, the ith subchannel is an additive white Gaussian noise (AWGN) channel.

We consider two scenarios for the vector of fading coefficients h=(h₁, h₂, h₃, h₄). The first scenario is a “no-fading” scenario, with h=(1,1,1,1). In the first scenario, each subchannel is a pure AWGN channel with no fading. The second scenario is a “block-fading” scenario, with h taking a value uniformly at random from the set 607. The second scenario corresponds to always having two of the four subchannels in outage. For example, h=(1,1,0,0) corresponds to having subchannels 3 and 4 in outage while the other two subchannels operate without any fading. The first scenario is defined as a benchmark for measuring the relative performance under the second block-fading scenario. This completes the specification of the channel 330 in the first embodiment.

The receiver 340 in the first embodiment operates according to the general methods already described above. The diversity demapper 341 in the first embodiment uses the log-likelihood ratios

$$ln \frac{{}^{p} ( {X}_{i , j} \vert {Y}_{1} , … , {Y}_{s} , {X}_{1} , … , {X}_{i - 1} ) ( {x}_{i , j} = 0 \vert {y}_{1} , … , {y}_{s} , {\hat{x}}_{1} , … , {\hat{x}}_{i - 1} )}{{}^{p} ( {X}_{i , j} \vert {Y}_{1} , … , {Y}_{s} , {X}_{1} , … , {X}_{i - 1} ) ( {x}_{i , j} = 1 \vert {y}_{1} , … , {y}_{s} , {\hat{x}}_{1} , … , {\hat{x}}_{i - 1} )} , \qquad 1 \leq j \leq N ,$$

as the ith stage decoder input statistics lᵢ, 1≤i≤r; the diversity demapper 341 computes the log-likelihood ratios with full knowledge of the noise variance σ² and the vector of block-fading coefficients h that is in effect for the current transmission. The decoder 342 in the first embodiment implements successive cancelation (SC) decoding.

A benchmark polar code for performance comparison. We will assess the performance of the first embodiment specified above by comparing the performance with a benchmark polar code. The benchmark polar code is a standard prior-art polar code that uses a polar transform F⊗ to encode data words of length K=26 to code words of length N=64. Thus, the dimensions of the benchmark polar code match those of the code in the first embodiment. In the benchmark polar code, the polar transform input word u=(u₁, u₂, . . . , u₆₄) contains frozen bits and data bits. The data bits are located in a set of positions indicated by a bit-selection vector, wherein the bit selection vector in the benchmark polar code equals (16, 24, 28, 30, 31, 32, 40, 44, 45, 46, 47, 48, 51, 52, 53, 54, 55, 56, 57, 58, 59, 60, 61, 62, 63, 64). This bit-selection vector is constructed using prior-art polar construction rules, following the 5G NR polar code specification. In the benchmark polar code, the frozen bits in the polar transform input word are set to zero. The encoding of the benchmark polar code is completed by calculating the code word as x=uF⊗. The benchmark polar code uses BPSK modulation over the same channel as we specified above for the first embodiment. There are 4 subchannels in the channel 330, and the segment (x₍ᵢ₋₁₎₁₆₊₁, . . . , xᵢ₋₁₆) of the code word x is sent over the ith subchannel, 1≤i≤4. The benchmark polar code is decoded by a standard successive cancellation (SC) decoder with full knowledge of the noise variance σ² and the vector of block-fading coefficients h that is in effect for the current transmission. The benchmark polar code is equipped with a channel interleaver, defined by the permutation π=(60, 30, 48, 54, 15, 3, 29, 9, 11, 1, 6, 41, 28, 37, 56, 43, 46, 18, 39, 19, 21, 58, 20, 26, 35, 5, 49, 52, 36, 2, 14, 42, 55, 61, 62, 47, 13, 27, 57, 4, 59, 51, 44, 24, 34, 45, 50, 22, 64, 17, 63, 31, 8, 40, 23, 10, 12, 16, 32, 25, 53, 38, 7, 33), which may be turned on or off. If interleaving is employed, the code word x is sent to the channel 330 in the permuted order π·x=(x₆₀, x₃₀, . . . , x₃₃). The permutation w has been found by trying 1000 randomly chosen permutations and choosing the best one. One of the advantages of the present principles is to make it unnecessary to use interleavers.

FIG. 6B is a chart 650 comparing the performance of the first embodiment of the present principles with that of the benchmark polar code. In the chart 650, the horizontal axis indicates the SNR in decibels (dB), where the SNR is defined, in terms of the AWGN noise variance α², as

$$S N R = 10 {log}_{10} \frac{1}{{σ}^{2}} ,$$

for the BPSK system here. The vertical axis corresponds to the frame error rate (FER). The curves 651 and 652 are the performance curves, under the first channel scenario, for the benchmark polar code and the polar-diversity code in the first embodiment, respectively. The curves 651 and 652 show that the present principles do not provide a gain over the benchmark polar code in the absence of channel fading. The curves 653 and 654 are performance curves for the benchmark polar code under the second channel scenario, with and without interleaving, respectively. The curves 653 and 654 show that, although interleaving helps, the benchmark polar code suffers from a severe error floor effect, and FER stops decreasing even as the SNR is increased to very high values. This is an indication that the benchmark polar code is unable to cope with channel outage events defined by the second channel scenario. The curve 655 shows the performance of the first embodiment of the present principles under the second channel scenario; there is no error floor and the performance improves as SNR is increased.

The chart 650 illustrates the practical utility of the present principles as a coding system designed to withstand extreme outage scenarios. Even if such extreme outage scenarios arise extremely rarely, they may be the main determinant of performance in applications that require extreme reliability subject to latency constraints. For example, a FER target of 10⁻¹² requires considering outage events of probability 10⁻¹². By outage events, we mean any event in the channel (such as interference, excess noise, etc.) that severely disrupts information transmission and renders the channel practically useless. The present principles increase the resilience of forward error correcting coding against such catastrophic outage events (curves 652 and 655), at the expense of some performance degradation under typical operating conditions (curves 651 and 652).

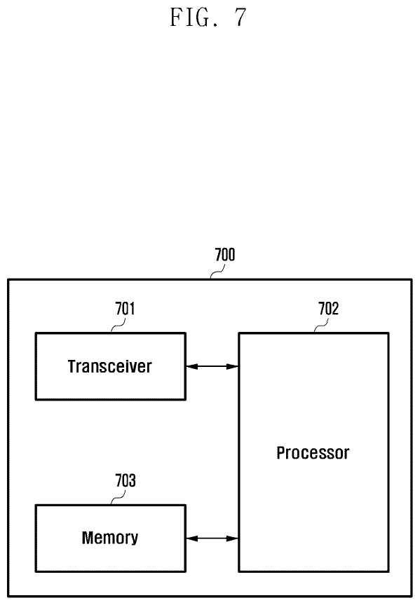

FIG. 7 is a block diagram of a terminal or UE 700 according to an embodiment of the disclosure.

The terminal is an electronic device capable of wireless communication, may include a User Equipment (UE), a portable phone, a smartphone, a tablet, an IoT device, etc., having various form factors, and may perform wireless communication with a base station through a wireless channel.

Referring to FIG. 7, the UE 700 may include at least one transceiver (hereinafter, referred to as simply “transceiver”) 701, at least one processor (hereinafter, referred to as simply “processor”) 702, and at least one memory (hereinafter, referred to as simply “memory”) 703. According to at least one or a combination of methods corresponding to the embodiments described above, the transceiver 701, the processor 702, and the memory 703 of the UE 700 may operate. However, components of the UE 700 are not limited to the exemplary components illustrated in FIG. 7. In another embodiment, the UE 700 may either include components further to the above-mentioned components or omit some of the components. Further, in some embodiments, the transceiver 701, the processor 702, or the memory 703 may be integrated in the form of one chip.

The transceiver 701 may be a communication circuit that enables the UE 700 to transmit or receive a signal to or from a base station through cellular communication. For example, the transceiver 701 may support at least one of various cellular communication technologies including 3G, 4G, Long Term Evolution (LTE), 5G new radio (NR), 6G, and wireless communications of all following evolved generations.

According to an embodiment, the UE 700 may include a plurality of transceivers. In the case of supporting E-UTRA-NR Dual Connectivity (EN-DC), the UE may include a first transceiver supporting the 4G LTE wireless communication and a second transceiver supporting the 5G NR wireless communication. According to another embodiment, in the case of supporting NR Dual Connectivity (NR-DC), the UE 700 may include a plurality of transceivers supporting the 5G NR wireless communication. According to still another embodiment, in the case of supporting near field wireless communication, the UE 700 may separately include a transceiver supporting at least one standard in the group of wireless communication protocol standards as defined in the protocol standards for the Bluetooth, wireless LAN, or WLAN network (including IEEE 802.11-2016 standard or its amendments, e.g., 802.11ah, 802.11ad, 802.11ay, 802.11ax, 802.11az, 802.11ba, and 802.11be, without being limited thereto).

According to an embodiment, the transceiver 701 may include various circuit structures used to transmit or receive signals to or from a base station through a wireless channel. The signals may include control information and data. For example, the transceiver 701 may include an RF transmitter for up-converting and amplifying the frequency of a transmitted signal and an RF receiver for low-noise-amplifying a received signal and down-converting the frequency thereof. The transceiver 701 may output a signal received through a wireless channel to the processor 702 and may transmit, through a wireless channel, a signal output from the processor 702.

The processor 702 may control general operations of the UE 700 according to embodiments of the disclosure described above. The processor 702 may be implemented by one or more integrated circuit (or circuitry) (IC) chips and may execute various data processing steps. The processor 702 may include at least one electric circuit, and may execute instructions (or a program, codes, data, etc.) stored in the memory 703, individually, collectively or in any combination thereof. Further, the processor 702 may include a single-core processor or multi-core processor, and may include a processor assembly including a plurality of processing circuits according to a specific implementation scheme.

The processor 702 may be electrically, operatively, or communicatively coupled to the transceiver 701 to control the transceiver 701.

The processor 702 may include at least one processor (or processor circuitry), and the at least one processor may perform the following operations individually, collectively or in any combination thereof. For example, the processor 702 may include a communication processor (CP) configured to control communication operations and an application processor (AP) configured to control execution of an upper layer (for example, an application layer). In a specific embodiment, at least a part of the processor 702 may be included in one chip and the other part of the processor 702 may be included in another chip. Otherwise, at least one processor may be included in another component, for example, the transceiver 701 or the memory 703.

The processor 702 may perform or control an operation of the UE for executing at least one or a combination of methods according to embodiments of the disclosure. For example, the processor 702 may control operations of the UE for processing a downlink signal received from a base station or generating and transmitting an uplink signal to a base station. To this end, the processor 702 may execute a computer program, codes, or instructions stored in the memory 703, so as to control other components of the UE 700 to enable execution of various operations.

The memory 703 corresponds to a hardware storage device capable of temporarily or permanently storing information and may include one or more storage media. For example, the memory 703 may include a memory assembly including one or more storage media. For example, the one or more storage media may include a permanent memory, such as a hard drive, a flash memory, or a read-only memory (ROM), a semipermanent memory, such as a random access memory (RAM), a cache memory, or a combination thereof.

The memory 703 may be electrically, operatively, or communicatively coupled to the processor 702 and may be accessed by the processor 702.

The memory 703 may store a computer program, codes, or instructions executable by the processor 702. According to an embodiment, a computer program, codes, or instructions executable by the processor 702 may be either stored in a single memory or separated and distributed to be stored in two or memories. By executing the instructions stored in the memory 703, the processor 702 may perform various functions according to an embodiment of the disclosure.

According to an embodiment of the disclosure, operations of a UE discussed below may be performed through a computer program, codes, or instructions stored in the memory 703 by at least one processor configured to perform features of the disclosure individually, collectively, or in any combination thereof, a processing circuitry configured not to execute instructions, or components of a processing circuitry configured not to execute instructions, individually, collectively, or in any combination thereof.

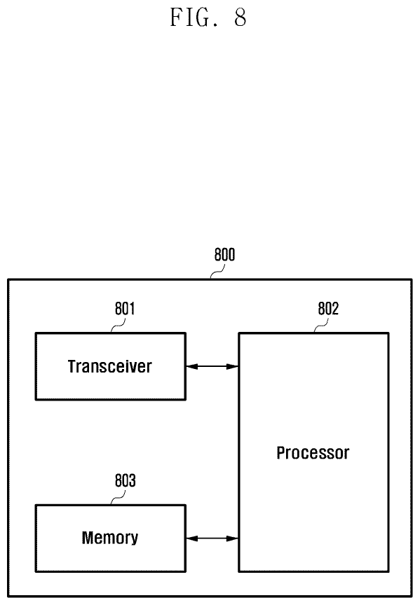

FIG. 8 is a block diagram of a base station 800 according to an embodiment of the disclosure.

The base station 800 may perform wireless communication with at least one UE located within the area of the base station 800 through a wireless channel.

Referring to FIG. 8, the base station 800 may include at least one transceiver (hereinafter, referred to as simply “transceiver”) 801, at least one processor (hereinafter, referred to as simply “processor”) 802, and at least one memory (hereinafter, referred to as simply “memory”) 803. According to at least one or a combination of methods corresponding to the embodiments described above, the transceiver 801, the processor 802, and the memory 803 of the base station 800 may operate. However, components of the base station 800 are not limited to the exemplary components illustrated in FIG. 8. In another embodiment, the base station 800 may either include components further to the above-mentioned components or omit some of the components. Further, in some embodiments, the transceiver 801, the processor 802, or the memory 803 may be integrated in the form of one chip.

The transceiver 801 may be a communication circuit that enables the base station 800 to transmit or receive a signal to or from the UE 700 through cellular communication. For example, the transceiver 801 may support various cellular communication technologies including 3G, 4G, Long Term Evolution (LTE), 5G new radio (NR), 6G, and wireless communications of all following evolved generations. According to an embodiment, the transceiver 801 may include various circuit structures used to transmit or receive signals to or from a UE through a wireless channel. The signals may include control information and data. For example, the transceiver 801 may include an RF transmitter for up-converting and amplifying the frequency of a transmitted signal and an RF receiver for low-noise-amplifying a received signal and down-converting the frequency thereof. The transceiver 801 may output a signal received through a wireless channel to the processor 802 and may transmit, through a wireless channel, a signal output from the processor 802.

The processor 802 may control general operations of the base station 800 according to embodiments of the disclosure described above. The processor 802 may be implemented by one or more integrated circuit (or circuitry) (IC) chips and may execute various data processing steps. The processor 802 may include at least one electric circuit, and may execute instructions (or a program, codes, data, etc.) stored in the memory 803, individually, collectively or in any combination thereof. Further, the processor 802 may include a single-core processor or multi-core processor, and may include a processor assembly including a plurality of processing circuits according to a specific implementation scheme.

The processor 802 may be electrically, operatively, or communicatively coupled to the transceiver 801 to control the transceiver 801.

The processor 802 may include at least one processor (or processor circuitry), and the at least one processor may perform the following operations individually, collectively or in any combination thereof. In a specific embodiment, at least a part of the processor 802 may be included in one chip and the other part of the processor 802 may be included in another chip. Otherwise, at least one processor may be included in another component, for example, the transceiver 801 or the memory 803.

The processor 802 may perform or control an operation of the base station for executing at least one or a combination of methods according to embodiments of the disclosure. For example, the processor 802 may control operations of the base station for generating and transmitting a downlink signal to a UE or processing an uplink signal received from a UE. Otherwise, the base station may transmit or receive a signal to or from a neighboring base station, transfer a signal received from a UE to an upper node of the network, or transmit a signal transferred from an upper node of the network to a UE. To this end, the processor 802 may execute a computer program, codes, or instructions stored in the memory 803, so as to control other components of the base station 800 to enable execution of various operations.

The memory 803 corresponds to a hardware storage device capable of temporarily or permanently storing information and may include one or more storage media. For example, the memory 803 may include a memory assembly including one or more storage media. For example, the one or more storage media may include a permanent memory, such as a hard drive, a flash memory, or a read-only memory (ROM), a semipermanent memory, such as a random access memory (RAM), a cache memory, or a combination thereof.

The memory 803 may be electrically, operatively, or communicatively coupled to the processor 802 and may be accessed by the processor 802.

The memory 803 may store a computer program, codes, or instructions executable by the processor 802. According to an embodiment, a computer program, codes, or instructions executable by the processor 802 may be either stored in a single memory or separated and distributed to be stored in two or memories. By executing the instructions stored in the memory 803, the processor 802 may perform various functions according to an embodiment of the disclosure.

According to an embodiment of the disclosure, operations of a base station discussed below may be performed through a computer program, codes, or instructions stored in the memory 803 by at least one processor configured to perform features of the disclosure individually, collectively, or in any combination thereof, a processing circuitry configured not to execute instructions, or components of a processing circuitry configured not to execute instructions, individually, collectively, or in any combination thereof.

While the particular METHODS AND APPARATUS FOR ERROR CORRECTION CODING COMBINED WITH DIVERSITY MAPPING is herein described in detail and is depicted in the drawings, it is to be understood that the subject matter which is encompassed by the present disclosure is limited only by the claims. Although the present disclosure has been described with exemplary embodiments, various changes and modifications may be suggested to one skilled in the art. It is intended that the present disclosure encompass such changes and modifications that fall within the scope of the appended claims. The description in the present application should not be read as implying that any particular element, step, or function is an essential or critical element which must be included in the claim scope: the scope of patented subject matter is defined only by the allowed claims. Moreover, none of these claims are intended to invoke 35 USC § 112(f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S.C. § 112(f).

Meanwhile, although specific embodiments of the present disclosure have been described in detail, various modifications may be made without departing from the scope of the present disclosure. Therefore, the scope of the present disclosure should not be limited to the described embodiments, but should be defined by the claims and equivalents thereof.

What is claimed is:

1. A transmitter apparatus in a communication system, the transmitter apparatus comprising:
memory storing instructions; and
processing circuitry coupled to the memory and configured, based at least partially on the instructions, to cause the transmitter apparatus to:
identify a data word d from a source,
identify a plurality of encoder output subwords x₁, x₂, . . . , xᵣ from the data word d based on an encoder input mapping relation and a plurality of encoding functions, wherein r is greater than one,
identify a plurality of channel input subwords v₁, v₂, . . . , vₛ from the plurality of encoder output subwords x₁, x₂, . . . , xᵣ based on a diversity transform and a subchannel assignment relation,
transmit the plurality of channel input subwords v₁, v₂, . . . , vₛ over a channel, wherein the channel comprises a plurality of subchannels, wherein s is related to a number of subchannels and s is greater than one.

2. The transmitter apparatus of claim 1, wherein the plurality of encoding functions comprises a plurality of encoding matrices G⁽¹⁾, G⁽²⁾, . . . , G^{(r)} and the processing circuitry is further configured, based at least partially on the instructions, to cause the transmitter apparatus to:
identify a plurality of encoder input subwords u₁, u₂, . . . , uᵣ from the data word d based on the encoder input mapping relation, and
identify the plurality of encoder output subwords x₁, x₂, . . . , xᵣ from the plurality of encoder input subwords u₁, u₂, . . . , uᵣ by computing
$${x}_{i , j} = {\sum }_{k = I}^{{M}_{i}} {u}_{i , k} {g}_{k , j}^{( i )}$$
for each 1≤i≤r and 1≤j≤N, wherein x_{i,j} is a jth element of xᵢ, wherein u_{i,k} is a kth element of uᵢ, wherein
$${g}_{k , j}^{( i )}$$
is a (k,j)th element of G⁽ⁱ⁾, wherein Mᵢ≥1 is a number of elements of uᵢ, wherein N is a number of elements of xᵢ, N satisfies N≥Mᵢ, and N is the same for each xᵢ, 1≤i≤r.

3. The transmitter apparatus of claim 1, wherein the diversity transform comprises a diversity transform matrix G_{DIV} and the processing circuitry is further configured, based at least partially on the instructions, to cause the transmitter apparatus to:
identify a plurality of diversity transform output subwords z₁, z₂, . . . , zₜ from the plurality of encoder output subwords x₁, x₂, . . . , xᵣ by computing
$${z}_{i , j} = {\sum }_{k = 1}^{r} {g}_{k , i}^{DIV} {x}_{k , j}$$
for each 1≤i≤t and 1≤j≤N, wherein z_{i,j} is a jth element of zᵢ, wherein x_{k,j} is a jth element of xₖ, wherein
$${g}_{k , i}^{DIV}$$
is a (k,i)th element of G_{DIV}, wherein is a number of elements of xᵢ and N is the same for each xᵢ, 1≤i≤r, wherein t is a number of diversity transform output subwords and t satisfies t>r,
identify the plurality of channel input subwords v₁, v₂, . . . , vₛ from the plurality of diversity transform output subwords z₁, z₂, . . . , zₜ based on the subchannel assignment relation.

4. The transmitter apparatus of claim 2, wherein the encoder input mapping relation comprises setting (uᵢ)_{D}_{ᵢ}=d_{B}_{ᵢ} for each 1≤i≤r, wherein (B₁, B₂, . . . , Bᵣ) is a non-trivial partition of {1, 2, . . . , K}, wherein (D₁, D₂, . . . , Dᵣ) is a collection of sets such that Dᵢ⊂{1, 2, . . . , Mᵢ}, wherein |D_i|= [symbol] B [symbol] _i| for each 1≤i≤r, wherein K is a number of elements of the data word d, wherein K≥2.

5. The transmitter apparatus of claim 4, wherein G⁽ⁱ⁾ is a polar transform matrix and Dᵢ is chosen based on a polar code design relation, wherein the polar code design relation comprises a ranking of reliabilities of the elements of uᵢ, wherein 1≤i≤r.

6. The transmitter apparatus of claim 3, wherein G_{DIV} is a r×t matrix over GF(2) obtained from a matrix G over a GF(2^{m}) by replacing each entry g_{i,j} ∈GF(2^{m}) of G with ϕ(g_{i,j}), where ϕ is representation of GF(2^{m}) using m×m matrices over GF(2), wherein m is greater than two.

7. The transmitter apparatus of claim 3, wherein the subchannel assignment relation comprises a subchannel assignment partition, wherein the subchannel assignment partition is a non-trivial partition [symbol] (A [symbol] ₁, A₂, . . . , Aₛ) of {1, 2, . . . , t}, wherein an ith diversity transform output subword zᵢ is assigned to the jth channel input subword vⱼ in case that i belongs to Aⱼ, for each 1≤i≤t and 1≤j≤s.

8. The transmitter apparatus of claim 3, wherein the diversity transform matrix G_{DIV} and a family of diversity transform output erasure scenarios ε={E_1, E_2, . . . , E_m} satisfy a full-rank criterion such that a matrix G_{DIV}(E^{c}) is a full-rank matrix for each E∈ε, wherein ε is related to a family of subchannel erasure scenarios [symbol] , wherein each element of [symbol] comprises an outage event involving at least one subchannel among the plurality of subchannels.

9. A method performed by a transmitter apparatus in a communication system, the method comprising:
an encoding step, wherein the encoding step comprises:
identifying a data word d from a source; and
identifying a plurality of encoder output subwords x₁, x₂, . . . , xᵣ from the data word d based on an encoder input mapping relation and a plurality of encoding functions, wherein r is greater than one; and
a diversity mapping step, wherein the diversity mapping step comprises:
identifying a plurality of channel input subwords v₁, v₂, . . . , vₛ from the plurality of encoder output subwords x₁, x₂, . . . , xᵣ based on a diversity transform and a subchannel assignment relation; and
transmitting the plurality of channel input subwords v₁, v₂, . . . , vₛ over a channel, wherein the channel comprises a plurality of subchannels, wherein s is related to a number of subchannels and s is greater than one.

10. The method of claim 9, wherein the plurality of encoding functions comprises a plurality of encoding matrices G⁽¹⁾, G⁽²⁾, . . . , G^{(r)} and the encoding step further comprises:
identifying a plurality of encoder input subwords u₁, u₂, . . . , uᵣ from the data word d based on the encoder input mapping relation, and
identifying the plurality of encoder output subwords x₁, x₂, . . . , xᵣ from the plurality of encoder input subwords u₁, u₂, . . . , uᵣ by computing
$${x}_{i , j} = {\sum }_{k = 1}^{{M}_{i}} {u}_{i , k} {g}_{k , j}^{( i )}$$
for each 1≤i≤r and 1≤j≤N, wherein x_{i,j} is a jth element of xᵢ, wherein u_{i,k} is a kth element of uᵢ, wherein
$${g}_{k , j}^{( i )}$$
is a (k,j)th element of G⁽ⁱ⁾, wherein Mᵢ≥1 is a number of elements of uᵢ, wherein N is a number of elements of xᵢ, N satisfies N≥Mᵢ, and N is the same for each xᵢ, 1≤i≤r.

11. The method of claim 9, wherein the diversity transform comprises a diversity transform matrix G_{DIV} and the method further comprises:
identifying a plurality of diversity transform output subwords z₁, z₂, . . . , zₜ from the plurality of encoder output subwords x₁, x₂, . . . , xᵣ by computing
$${z}_{i , j} = {\sum }_{k = 1}^{r} {g}_{k , i}^{DIV} {x}_{k , j}$$
for each 1≤i≤t and 1≤j≤N, wherein z_{i,j} is a jth element of zᵢ, wherein x_{k,j} is a jth element of xₖ, wherein
$${g}_{k , i}^{DIV}$$
is a (k,i)th element of G_{DIV}, wherein N is a number of elements of xᵢ and N is the same for each 1≤i≤r, wherein t is a number of diversity transform output subwords and t satisfies t>r,
identifying the plurality of channel input subwords v₁, v₂, . . . , vₛ from the plurality of diversity transform output subwords z₁, z₂, . . . , zₜ based on the subchannel assignment relation.

12. The method of claim 10, wherein the encoder input mapping relation comprises setting (uᵢ)_{D}_{ᵢ}=d_{B}_{ᵢ} for each 1≤i≤r, wherein (B₁, B₂, . . . , Bᵣ) is a non-trivial partition of {1, 2, . . . , K}, wherein (D₁, D₂, . . . , Dᵣ) is a collection of sets such that Dᵢ⊂{1, 2, . . . , Mᵢ}, wherein |D_i|= [symbol] B [symbol] _i| for each 1≤i≤r, wherein K is a number of elements of the data word d, wherein K≥2.

13. The method of claim 12, wherein G⁽ⁱ⁾ is a polar transform matrix and Dᵢ is chosen based on a polar code design relation, wherein the polar code design relation comprises a ranking of reliabilities of the elements of uᵢ, wherein 1≤i≤r.

14. The method of claim 11, wherein G_{DIV} is a r×t matrix over GF(2) obtained from a matrix G over a GF(2^{m}) by replacing each entry g_{i,j}⊂GF(2^{m}) of G with ϕ(g_{i,j}), where ϕ is representation of GF(2^{m}) using m×m matrices over GF(2), wherein m is greater than two.

15. The method of claim 11, wherein the subchannel assignment relation comprises a subchannel assignment partition, wherein the subchannel assignment partition is a non-trivial partition [symbol] (A [symbol] ₁, A₂, . . . , Aₛ) of {1, 2, . . . , t}, wherein the ith diversity transform output subword zᵢ is [symbol] assigned to the th channel input subword vⱼ in case that i belongs to Aⱼ, for each 1≤i≤t and 1≤j≤s.

16. The method of claim 11, wherein the diversity transform matrix G_{DIV} and a family of diversity transform output erasure scenarios ε={E_1, E_2, . . . , E_m} satisfy a full-rank criterion such that a matrix G_{DIV}(E^{c}) is a full-rank matrix for each E␣ε, wherein ε is related to a family of subchannel erasure scenarios [symbol] , wherein each element of [symbol] comprises an outage event involving at least one subchannel among the plurality of subchannels.

17. A receiver apparatus in a communication system, the receiver apparatus comprising:
memory storing instructions; and
processing circuitry coupled to the memory and configured, based at least partially on the instructions, to cause the receiver apparatus to:
receive a plurality of channel output subwords y₁, y₂, . . . , yₛ from a channel, wherein the channel comprises a plurality of subchannels, wherein s is related to a number of subchannels and s is greater than one,
identify an ith decoder input statistic lᵢ in an ith iteration of a receiver process, wherein the ith decoder input statistic lᵢ is based on y₁, y₂, . . . , yₛ, any decision feedback messages in iterations prior to the ith iteration, and a diversity transform matrix G_{DIV}, wherein G_{DIV} is a r×t matrix with t>r≥2,
send the ith decoder input statistic lᵢ, and
obtain an ith decision feedback message; and
obtain the ith decoder input statistic lᵢ,
identify an ith partial decoder decision based on the ith decoder input statistic lᵢ, wherein the ith partial decoder decision comprises an ith decoded encoder input subword ûᵢ,
determine whether an ith termination condition is satisfied,
in case that the ith termination condition is not satisfied, identify an ith decision feedback message and send the ith decision feedback message, wherein the ith decision feedback message is based on the ith partial decoder decision and comprises an ith decoded encoder output subword \hat{x}ᵢ, wherein \hat{x}ᵢ is obtained from the ith decoded encoder input subword ûᵢ based on an ith encoding function, wherein the ith encoding function comprises an ith encoding matrix G⁽ⁱ⁾ with Mᵢ rows and N columns, wherein Mᵢ is a number of elements of ûᵢ, wherein N is a number of elements of \hat{x}ᵢ, wherein 1≤Mᵢ≤N, wherein N is the same for each \hat{x}ᵢ, 1≤i≤r,
in case that an termination condition is satisfied, identify a decoder output and sending the decoder output to a destination, wherein the decoder output comprises a decoded data word \hat{d}, wherein \hat{d}_{B}_{ᵢ}=(ûᵢ)_{D}_{ᵢ} for each 1≤i≤r, wherein (B₁, B₂, . . . , Bᵣ) is a non-trivial partition of {1, 2, . . . , K}, wherein (D₁, D₂, . . . , Dᵣ) is a collection of sets such that Dᵢ⊂{1, 2, . . . , Mᵢ}, wherein |D_i|= [symbol] B [symbol] _i| for each 1≤i≤r, wherein K is a number of elements of \hat{d}, wherein K≥2.

18. The receiver apparatus of claim 17, wherein the diversity transform matrix G_{DIV} and a family of diversity transform output erasure scenarios E={E_1, E_2, . . . , E_m} satisfy a full-rank criterion such that a matrix G_{DIV}(E^{c}) is a full-rank matrix for each E∈ε, wherein E is related to a family of subchannel erasure scenarios [symbol] , wherein each element of [symbol] comprises an outage event involving at least one subchannel among the plurality of subchannels.

19. The receiver apparatus of claim 17, wherein the ith encoding function comprises a polar transform matrix and Mᵢ=N for all 1≤i≤r.

20. A method performed by a receiver apparatus in a communication system, the method comprising:
receiving a plurality of channel output subwords y₁, y₂, . . . , yₛ from a channel, wherein the channel comprises a plurality of subchannels, wherein s is related to a number of subchannels and s is greater than one, and
identifying an ith decoder input statistic lᵢ in an ith iteration of a receiver process, wherein the ith decoder input statistic lᵢ is based on y₁, y₂, . . . , yₛ, any decision feedback messages in iterations prior to the ith iteration, and a diversity transform matrix G_{DIV}, wherein G_{DIV} is a r×t matrix with t>r≥2,
sending the ith decoder input statistic lᵢ, and
obtaining an ith decision feedback message; and
obtaining the ith decoder input statistic lᵢ,
identifying an ith partial decoder decision based on the ith decoder input statistic lᵢ, wherein the ith partial decoder decision comprises an ith decoded encoder input subword ûᵢ,
determining whether an ith termination condition is satisfied,
in case that the ith termination condition is not satisfied, identifying an ith decision feedback message and sending the ith decision feedback message, wherein the ith decision feedback message is based on the ith partial decoder decision and comprises an ith decoded encoder output subword \hat{x}ᵢ, wherein \hat{x}ᵢ is obtained from the ith decoded encoder input subword ûᵢ based on an ith encoding function, wherein the ith encoding function comprises an ith encoding matrix G⁽ⁱ⁾ with Mᵢ rows and N columns, wherein Mᵢ is a number of elements of ûᵢ, wherein N is a number of elements of \hat{x}ᵢ, wherein 1≤Mᵢ≤N, wherein N is the same for each \hat{x}ᵢ, 1≤i≤r,
in case that an termination condition is satisfied, identifying a decoder output and sending the decoder output to a destination, wherein the decoder output comprises a decoded data word \hat{d}, wherein \hat{d}_{B}=(ûᵢ)_{D}_{ᵢ} for each 1≤i≤r, wherein (B₁, B₂, . . . , Bᵣ) is a non-trivial partition of {1, 2, . . . , K}, wherein (D₁, D₂, . . . , Dᵣ) is a collection of sets such that Dᵢ⊂{1, 2, . . . , Mᵢ}, wherein |D_i|= [symbol] B [symbol] _i| for each 1≤i≤r, wherein K is a number of elements of \hat{d}, wherein K≥2.

21. The method of claim 20, wherein the diversity transform matrix G_{DIV} and a family of diversity transform output erasure scenarios ε={E_1, E_2, . . . , E_m} satisfy a full-rank criterion such that a matrix G_{DIV}(E^{c}) is a full-rank matrix for each E∈ε, wherein ε is related to a family of subchannel erasure scenarios [symbol] , wherein each element of [symbol] comprises an outage event involving at least one subchannel among the plurality of subchannels.

22. The method of claim 20, wherein the ith encoding function comprises a polar transform matrix and Mᵢ=N for all 1≤i≤r.
